(19) United States
(12) Patent Application Publication
(10) Pub. No.: US 2025/0267908 A1
(43) Pub. Date: Aug. 21, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Tefu YEH, Kaohsiung City (TW); Chun-Liang CHEN, Hsinchu City (TW); Jo-Chun HUNG, Hsinchu City (TW); Ying-Liang CHUANG, Zhubei City (TW)

(21) Appl. No.: 18/583,209

(22) Filed: Feb. 21, 2024

(51) Int. Cl. H01L 29/06; H01L 21/8238; H01L 27/092; H01L 29/423; H01L 29/49; H01L 29/66; H01L 29/775; H01L 29/786

(52) U.S. Cl. CPC H10D 62/121; H10D 30/014; H10D 30/43; H10D 30/6735; H10D 30/6757; H10D 64/017; H10D 64/665; H10D 84/0167; H10D 84/038; H10D 84/85

(57) ABSTRACT

Techniques described herein include forming respective (different) types of gate metals for a p-type metal oxide semiconductor (PMOS) nanostructure transistor and keep intrinsic n-type metal oxide semiconductor (NMOS) nanostructure transistor of the semiconductor device. A p-type gate metal may be formed around nanostructure channels for the PMOS nanostructure transistor. The surface of the p-type gate metal may then be oxidized to form a metal oxide layer on the p-type gate metal. During formation of an n-type gate metal around the nanostructure channels for the NMOS nanostructure transistor, the metal oxide layer on the p-type gate metal resists formation of the n-type gate metal on the p-type gate metal. This results in little to no n-type gate metal deposition on the p-type gate metal, which minimizes the p-type threshold voltage (PVₜ) impact to the PMOS nanostructure transistor.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, nanoribbons, nanotubes, multi-bridge channels, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A and 3B are diagrams of an example implementation of a fin formation process described herein.

FIGS. 4A and 4B are diagrams of an example implementation of a shallow trench isolation (STI) process described herein.

FIGS. 5 and 6 are diagrams of an example dummy gate structure formation process described herein.

FIGS. 7A-7D are diagrams of example implementations of a source/drain recess formation process and an inner spacer formation process described herein.

FIG. 8 is a diagram of an example implementation of a source/drain region formation process described herein.

FIG. 9 is a diagram of an example implementation of an interlayer dielectric layer formation process described herein.

FIGS. 10A-10L are diagrams of an example implementation of a replacement gate process described herein.

FIG. 11 is a diagram of an example of n-metal thicknesses for various types of p-metal oxidation techniques described herein.

FIG. 12 is a diagram of an example of flat-band voltages of a p-type gate structure for various types of p-metal oxidation techniques described herein.

FIG. 13 is a diagram of example components of one or more devices described herein.

FIGS. 14 and 15 are flowcharts of example processes associated with forming a semiconductor device described herein.

FIGS. 16A and 16B are diagrams of an example implementation of a replacement gate process described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A nanostructure transistor may include a gate structure that wraps around a plurality of nanostructure channels. The gate structure wrapping around the nanostructure channels increases control of the gate structure over a conductive channel in the nanostructure channels, increases drive current for the nanostructure transistor, and/or may reduce short channel effects (SCEs) for the nanostructure transistor, among other examples. In some cases, a semiconductor device may include p-type metal oxide semiconductor (PMOS) nanostructure transistors and n-type metal oxide semiconductor (NMOS) nanostructure transistors. Integrating PMOS nanostructure transistors and NMOS nanostructure transistors into the same semiconductor device enables complementary metal oxide semiconductor (CMOS) integrated circuits to be realized in the semiconductor device. CMOS integrated circuits have many use cases in the semiconductor industry, including microprocessors (e.g., central processing units (CPUs)), graphics processing units (GPUs)), memory devices, digital logic circuitry, image sensors (e.g., CMOS image sensors), and/or radio frequency (RF) circuitry, among other examples.

The threshold voltage (Vt) for a nanostructure transistor is the required gate voltage to selectively turn the nanostructure transistor on or off. If the threshold voltage for the nanostructure transistor is too low (meaning that the gate voltage for activating the nanostructure transistor is too low), the nanostructure transistor may experience a high amount of current leakage when the nanostructure transistor is off. Conversely, if the threshold voltage for the nanostructure transistor is too high, the power efficiency of the nanostructure transistor may be degraded because higher gate voltages are needed to operate the nanostructure transistor. For PMOS nanostructure transistors and NMOS nanostructure transistors, the types of metals that are used for the gate structures may directly impact the threshold voltages for the PMOS nanostructure transistors and the NMOS nanostructure transistors. Metals that tune the work function (φₘ) of a gate structure for optimal performance of a PMOS nanostructure transistor may result in a large band gap between the work function of a gate structure of an NMOS nanostructure transistor and the conduction band (E_{C}), resulting in a high threshold voltage (and low power efficiency) for the NMOS nanostructure transistor. Metals that tune the work function of a gate structure for optimal performance of an NMOS nanostructure transistor may result in a large band gap between the work function of a gate structure of a PMOS nanostructure transistor and the valance band (E_{V}), resulting in a high threshold voltage (and low power efficiency) for the PMOS nanostructure transistor.

Some implementations described herein provide semiconductor manufacturing techniques and associated semiconductor structures for forming PMOS nanostructure transistors and NMOS nanostructure transistors in a semiconductor device. The techniques described herein include forming respective (different) types of gate metals for a PMOS nanostructure transistor and keep an intrinsic NMOS nanostructure transistor of the semiconductor device. A p-type gate metal may be formed around nanostructure channels for the PMOS nanostructure transistor. The surface of the p-type gate metal may then be oxidized to form a metal oxide layer on the p-type gate metal. During formation of an n-type gate metal around the nanostructure channels for the NMOS nanostructure transistor, the metal oxide layer on the p-type gate metal resists formation of the n-type gate metal on the p-type gate metal. This results in little to no n-type gate metal deposition on the p-type gate metal, which minimizes the p-type threshold voltage (PVₜ) impact to the PMOS nanostructure transistor. In this way, the techniques described herein enable the work functions of the NMOS nanostructure transistor and the PMOS nanostructure transistor to both be tuned for achieving desirable threshold voltages for the NMOS nanostructure transistor and the PMOS nanostructure transistor. This enables low current leakages to be achieved for the NMOS nanostructure transistor and the PMOS nanostructure transistor, and enables a high operating efficiency to be achieved for the NMOS nanostructure transistor and the PMOS nanostructure transistor.

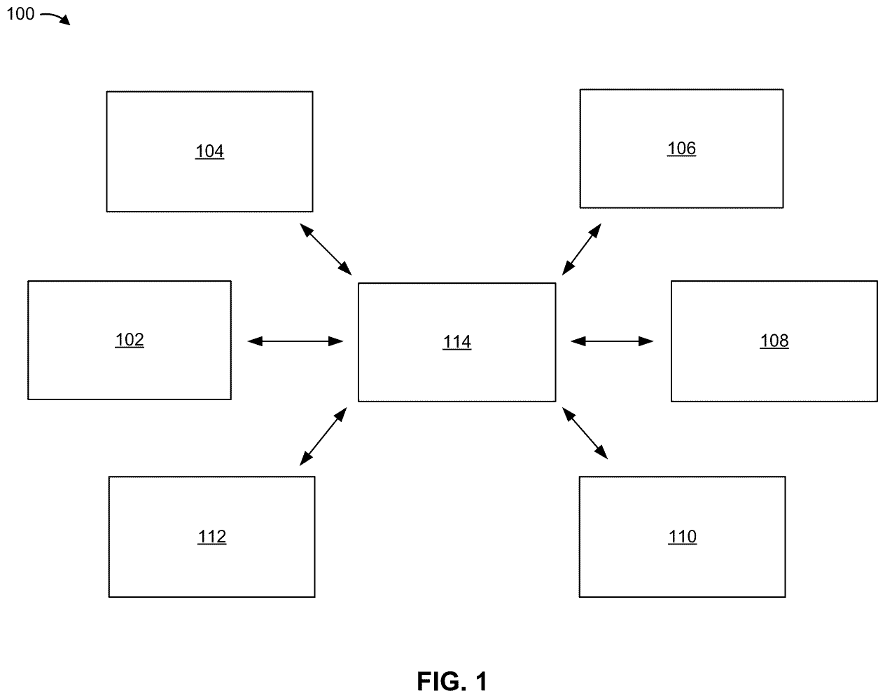

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that can be filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material and/or another material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

As described herein, the semiconductor processing tools 102-112 may perform a combination of operations to form one or more portions of a nanostructure transistor. In some implementations, the combination of operations includes forming a first plurality of nanostructure channel layers that are arranged in a direction that is approximately perpendicular to a semiconductor substrate of a semiconductor device; forming a second plurality of nanostructure channel layers that are arranged in the direction that is approximately perpendicular to the semiconductor substrate; forming a p-type metal layer of a first gate structure such that the p-type metal layer wraps around each of the first plurality of nanostructure channel layers; forming a metal oxide layer on the p-type metal layer; and/or forming, after forming the metal oxide layer, an n-type metal layer of a second gate structure such that the n-type metal layer wraps around each of the second plurality of nanostructure channel layers, among other examples.

In some implementations, the combination of operations includes forming a first plurality of nanostructure channel layers that are arranged in a direction that is approximately perpendicular to a semiconductor substrate of a semiconductor device; forming a second plurality of nanostructure channel layers that are arranged in the direction that is approximately perpendicular to the semiconductor substrate; forming a p-type metal layer such that the p-type metal layer wraps around each of the first plurality of nanostructure channel layers and around each of the second plurality of nanostructure channel layers; forming a masking layer over the first plurality of nanostructure channel layers; removing, while the masking layer is over the first plurality of nanostructure channel layers, a portion of the p-type metal layer from the second plurality of nanostructure channel layers, where a remaining portion of the p-type metal layer wrapping around the first plurality of nanostructure channel layers corresponds to a first gate structure; removing the masking layer after removing the portion of the p-type metal layer; performing, after removing the masking layer, an oxidation operation to form a metal oxide layer on the p-type metal layer of the first gate structure; and/or forming, after forming the metal oxide layer, an n-type metal layer of a second gate structure such that the n-type metal layer wraps around each of the second plurality of nanostructure channel layers, among other exmaples.

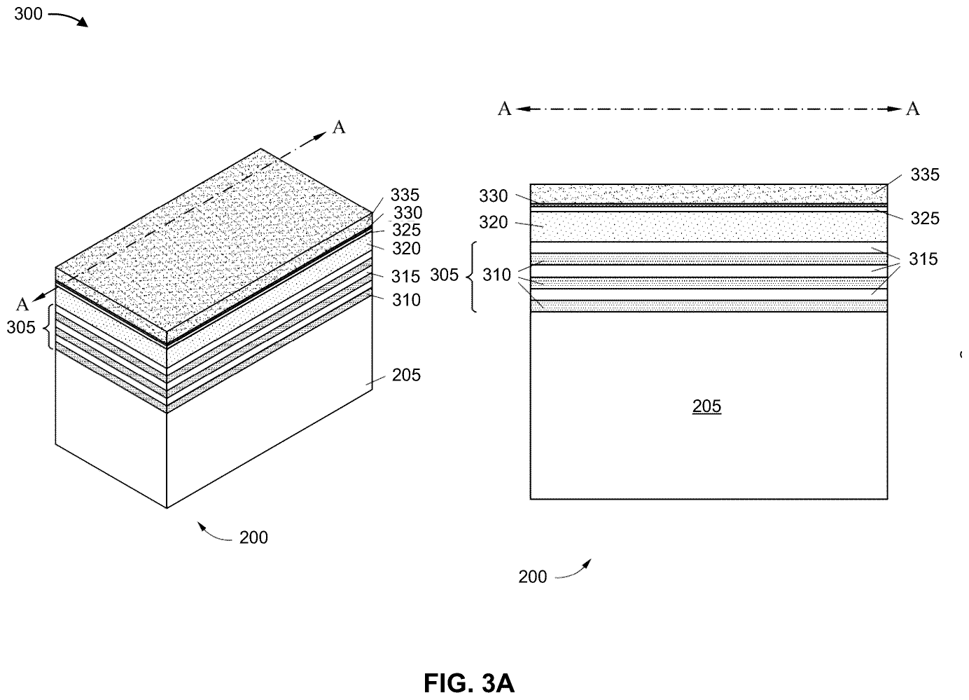

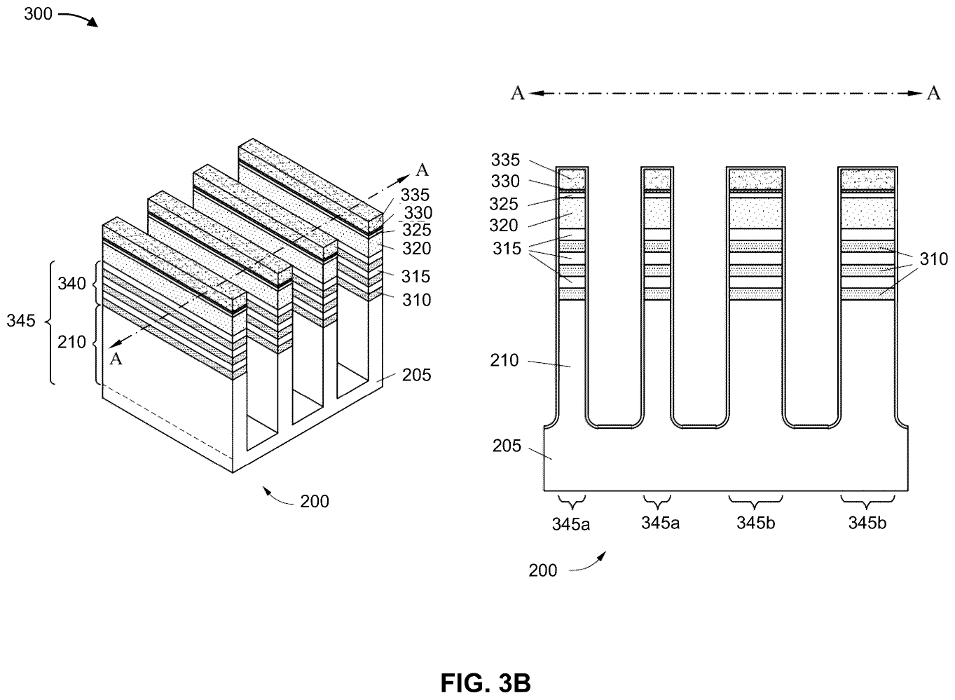

In some implementations, the combination of operations includes one or more operations described in connection with one or more of FIGS. 3A, 3B, 4A, 4B, 5, 6, 7A-7D, 8, 9, 10A-10L, 15, and/or 16, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

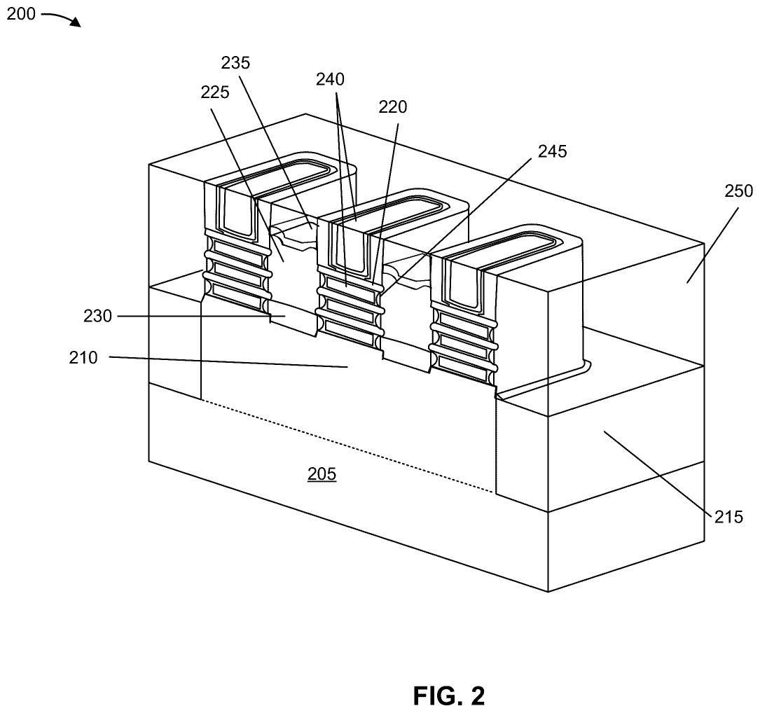

FIG. 2 is a diagram of an example semiconductor device 200 described herein. The semiconductor device 200 includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 200 may include one or more additional devices, structures, and/or layers not shown in FIG. 2. For example, the semiconductor device 200 may include additional layers and/or dies formed on layers above and/or below the portion of the semiconductor device 200 shown in FIG. 2. Additionally, or alternatively, one or more additional semiconductor structures and/or semiconductor devices may be formed in a same layer of an electronic device or integrated circuit (IC) that includes the semiconductor device as the semiconductor device 200 shown in FIG. 2. One or more of FIGS. 3A-12B may include schematic cross-sectional views of various portions of the semiconductor device 200 illustrated in FIG. 2, and correspond to various processing stages of forming nanostructure transistors of the semiconductor device 200.

The semiconductor device 200 includes a semiconductor substrate 205. The semiconductor substrate 205 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The semiconductor substrate 205 may include various layers, including conductive or insulating layers formed on a semiconductor substrate. The semiconductor substrate 205 may include a compound semiconductor and/or an alloy semiconductor. The semiconductor substrate 205 may include various doping configurations to satisfy one or more design parameters. For example, different doping profiles (e.g., n-wells, p-wells) may be formed on the semiconductor substrate 205 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 205 may include an epitaxial layer (epi-layer), may be strained for performance enhancement, and/or may have other suitable enhancement features. The semiconductor substrate 205 may include a portion of a semiconductor wafer on which other semiconductor devices are formed.

Mesa regions 210 are included above (and/or extend above) the semiconductor substrate 205. A mesa region 210 provides a structure on which nanostructures of the semiconductor device 200 are formed, such as nanostructure channels, nanostructure gate portions that wrap around each of the nanostructure channels, and/or sacrificial nanostructures, among other examples. In some implementations, one or more mesa regions 210 are formed in and/or from a fin structure (e.g., a silicon fin structure) that is formed in the semiconductor substrate 205. The mesa regions 210 may include the same material as the semiconductor substrate 205 and are formed from the semiconductor substrate 205. In some implementations, the mesa regions 210 are doped to form different types of nanostructure transistors, such as p-type nanostructure transistors and/or n-type nanostructure transistors. In some implementations, the mesa regions 210 include silicon (Si) materials or another elementary semiconductor material such as germanium (Ge). In some implementations, the mesa regions 210 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The mesa regions 210 are fabricated by suitable semiconductor process techniques, such as masking, photolithography, and/or etch processes, among other examples. As an example, fin structures may be formed by etching a portion of the semiconductor substrate 205 away to form recesses in the semiconductor substrate 205. The recesses may then be filled with isolating material that is recessed or etched back to form shallow trench isolation (STI) regions 215 above the semiconductor substrate 205 and between the fin structures. Source/drain recesses may be formed in the fin structures, which results in formation of the mesa regions 210 between the source/drain recesses. However, other fabrication techniques for the STI regions 215 and/or for the mesa regions 210 may be used.

The STI regions 215 may electrically isolate adjacent fin structures and may provide a layer on which other layers and/or structures of the semiconductor device 200 are formed. The STI regions 215 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 215 may include a multi-layer structure, for example, having one or more liner layers.

The semiconductor device 200 includes a plurality of nanostructure channels 220 that extend between, and are electrically coupled with, source/drain regions 225. “Source/drain region(s)” may refer to a source or a drain, individually or collectively dependent upon the context. The nanostructure channels 220 are arranged in a direction that is approximately perpendicular to the semiconductor substrate 205. In other words, the nanostructure channels 220 are vertically arranged or stacked above the semiconductor substrate 205.

The nanostructure channels 220 include silicon-based nanostructures (e.g., nanosheets or nanowires, among other examples) that function as the semiconductive channels of the nanostructure transistor(s) of the semiconductor device 200. In some implementations, the nanostructure channels 220 may include silicon germanium (SiGe) or another silicon-based material. The source/drain regions 225 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions, n-type metal-oxide semiconductor (NMOS) nanostructure transistors that include n-type source/drain regions, and/or other types of nanostructure transistors.

In some implementations, a buffer region 230 is included under a source/drain region 225, between the source/drain region 225 and a fin structure above the semiconductor substrate 205. A buffer region 230 may provide isolation between a source/drain region 225 and adjacent mesa regions 210. A buffer region 230 may be included to reduce, minimize, and/or prevent electrons from traversing into the mesa regions 210 (e.g., instead of through the nanostructure channels 220, thereby reducing current leakage), and/or may be included to reduce, minimize and/or prevent dopants from the source/drain region 225 into the mesa regions 210 (which reduces short channel effects).

A capping layer 235 may be included over and/or on the source/drain region 225. The capping layer 235 may include silicon, silicon germanium, doped silicon, doped silicon germanium, and/or another material. The capping layer 235 may be included to reduce dopant diffusion and to protect the source/drain regions 225 in semiconductor processing operations for the semiconductor device 200 prior to contact formation. Moreover, the capping layer 235 may contribute to metal-semiconductor (e.g., silicide) alloy formation.

At least a subset of the nanostructure channels 220 extend through one or more gate structures 240. The gate structures 240 may be formed of one or more metal materials, one or more high dielectric constant (high-k) materials, and/or one or more other types of materials. In some implementations, dummy gate structures (e.g., polysilicon (PO) gate structures or another type of gate structures) are formed in the place of (e.g., prior to formation of) the gate structures 240 so that one or more other layers and/or structures of the semiconductor device 200 may be formed prior to formation of the gate structures 240. This reduces and/or prevents damage to the gate structures 240 that would otherwise be caused by the formation of the one or more layers and/or structures. A replacement gate process (RGP) is then performed to remove the dummy gate structures and replace the dummy gate structures with the gate structures 240 (e.g., replacement gate structures).

As further shown in FIG. 2, portions of a gate structure 240 are formed in between pairs of nanostructure channels 220 in an alternating vertical arrangement. In other words, the semiconductor device 200 includes one or more vertical stacks of alternating nanostructure channels 220 and portions of a gate structure 240, as shown in FIG. 2. In this way, a gate structure 240 wraps around an associated nanostructure channel 220 on multiple sides of the nanostructure channel 220, which increases control of the nanostructure channel 220, increases drive current for the nanostructure transistor(s) of the semiconductor device 200, and reduces short channel effects (SCEs) for the nanostructure transistor(s) of the semiconductor device 200.

Some source/drain regions 225 and gate structures 240 may be shared between two or more nanoscale transistors of the semiconductor device 200. In these implementations, one or more source/drain regions 225 and a gate structure 240 may be connected or coupled to a plurality of nanostructure channels 220, as shown in the example in FIG. 2. This enables the plurality of nanostructure channels 220 to be controlled by a single gate structure 240 and a pair of source/drain regions 225.

Inner spacers (InSPs) 245 may be included between a source/drain region 225 and an adjacent gate structure 240. In particular, inner spacers 245 may be included between a source/drain region 225 and portions of a gate structure 240 that wrap around a plurality of nanostructure channels 220. The inner spacers 245 are included on ends of the portions of the gate structure 240 that wrap around the plurality of nanostructure channels 220. The inner spacers 245 are included in cavities that are formed in between end portions of adjacent nanostructure channels 220. The inner spacer 245 are included to reduce parasitic capacitance and to protect the source/drain regions 225 from being etched in a nanosheet release operation to remove sacrificial nanosheets between the nanostructure channels 220. The inner spacers 245 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The semiconductor device 200 may also include an inter-layer dielectric (ILD) layer 250 above the STI regions 215. The ILD layer 250 may be referred to as an ILDO layer. The ILD layer 250 surrounds the gate structures 240 to provide electrical isolation and/or insulation between the gate structures 240 and/or the source/drain regions 225, among other examples. Conductive structures such as contacts and/or interconnects may be formed through the ILD layer 250 to the source/drain regions 225 and the gate structures 240 to provide control of the source/drain regions 225 and the gate structures 240.

As indicated above, FIG. 2 is provided as an example. Other examples may differ from what is described with regard to FIG. 2.

FIGS. 3A and 3B are diagrams of an example implementation 300 of a fin formation process described herein. The example implementation 300 includes an example of forming fin structures for the semiconductor device 200 or a portion thereof. The semiconductor device 200 may include one or more additional devices, structures, and/or layers not shown in FIGS. 3A and 3B. The semiconductor device 200 may include additional layers and/or dies formed on layers above and/or below the portion of the semiconductor device 200 shown in FIGS. 3A and 3B. Additionally, or alternatively, one or more additional semiconductor structures and/or semiconductor devices may be formed in a same layer of an electronic device that includes the semiconductor device 200.

FIG. 3A illustrates a perspective view of the semiconductor device 200 and a cross-sectional view along the line A-A in the perspective view. As shown in FIGS. 3A, processing of the semiconductor device 200 is performed in connection with the semiconductor substrate 205. A layer stack 305 is formed on the semiconductor substrate 205. The layer stack 305 may be referred to as a superlattice. In some implementations, one or more operations are performed in connection with the semiconductor substrate 205 prior to formation of the layer stack 305. For example, an anti-punch-through (APT) implant operation may be performed. The APT implant operation may be performed in one or more regions of the semiconductor substrate 205 above which the nanostructure channels 220 are to be formed. The APT implant operation is performed, for example, to reduce and/or prevent punch-through or unwanted diffusion into the semiconductor substrate 205.

The layer stack 305 includes a plurality of alternating layers that are arranged in a direction that is approximately perpendicular to the semiconductor substrate 205. For example, the layer stack 305 includes vertically alternating layers of first layers 310 and second layers 315 above the semiconductor substrate 205. The quantity of the first layers 310 and the quantity of the second layers 315 illustrated in FIG. 3A are examples, and other quantities of the first layers 310 and the second layers 315 are within the scope of the present disclosure. In some implementations, the first layers 310 and the second layers 315 are formed to different thicknesses. For example, the second layers 315 may be formed to a thickness that is greater than a thickness of the first layers 310. In some implementations, the first layers 310 (or a subset thereof) are formed to a thickness in a range of approximately 4 nanometers to approximately 7 nanometers. In some implementations, the second layers 315 (or a subset thereof) are formed to a thickness in a range of approximately 8 nanometers to approximately 12 nanometers. However, other values for the thickness of the first layers 310 and for the thickness of the second layers 315 are within the scope of the present disclosure.

The first layers 310 include a first material composition, and the second layers 315 include a second material composition. In some implementations, the first material composition and the second material composition are the same material composition. In some implementations, the first material composition and the second material composition are different material compositions. As an example, the first layers 310 may include silicon germanium (SiGe) and the second layers 315 may include silicon (Si). In some implementations, the first material composition and the second material composition have different oxidation rates and/or etch selectivity.

As described herein, the second layers 315 may be processed to form the nanostructure channel 220 for subsequently-formed nanostructure transistors of the semiconductor device 200. The first layers 310 are sacrificial nanostructures that are eventually removed and serve to define a vertical distance between adjacent nanostructure channels 220 for a subsequently-formed gate structure 240 of the semiconductor device 200. Accordingly, the first layers 310 are referred to herein as sacrificial layers, and the second layers 315 may be referred to as channel layers.

The deposition tool 102 deposits and/or grows the alternating layers of the layer stack 305 to include nanostructures (e.g., nanosheets) on the semiconductor substrate 205. For example, the deposition tool 102 grows the alternating layers by epitaxial growth. However, other processes may be used to form the alternating layers of the layer stack 305. Epitaxial growth of the alternating layers of the layer stack 305 may be performed by a molecular beam epitaxy (MBE) process, a metalorganic chemical vapor deposition (MOCVD) process, and/or another suitable epitaxial growth process. In some implementations, the epitaxially grown layers such as the second layers 315 include the same material as the material of the semiconductor substrate 205. In some implementations, the first layers 310 and/or the second layers 315 include a material that is different from the material of the semiconductor substrate 205. As described above, in some implementations, the first layers 310 include epitaxially grown silicon germanium (SiGe) layers and the second layers 315 include epitaxially grown silicon (Si) layers. Alternatively, the first layers 310 and/or the second layers 315 may include other materials such as germanium (Ge), a compound semiconductor material such as silicon carbide (SiC), gallium arsenide (GaAs), gallium phosphide (GaP), indium phosphide (InP), indium arsenide (IAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The material(s) of the first layers 310 and/or the material(s) of the second layers 315 may be chosen based on providing different oxidation properties, different etching selectivity properties, and/or other different properties.

As further shown in FIG. 3A, the deposition tool 102 may form one or more additional layers over and/or on the layer stack 305. For example, a hard mask (HM) layer 320 may be formed over and/or on the layer stack 305 (e.g., on the top-most second layer 315 of the layer stack 305). As another example, a capping layer 325 may be formed over and/or on the hard mask layer 320. As another example, another hard mask layer including an oxide layer 330 and a nitride layer 335 may be formed over and/or on the capping layer 325. The one or more hard mask layers 320, 325, and 330 may be used to form one or more structures of the semiconductor device 200. The oxide layer 330 may function as an adhesion layer between the layer stack 305 and the nitride layer 335, and may act as an etch stop layer for etching the nitride layer 335. The one or more hard mask layers 320, 325, and 330 may include silicon germanium (SiGe), a silicon nitride (SiₓN_{y}), a silicon oxide (SiOₓ), and/or another material. The capping layer 325 may include silicon (Si) and/or another material. In some implementations, the capping layer 325 is formed of the same material as the semiconductor substrate 205. In some implementations, the one or more additional layers are thermally grown, deposited by CVD, PVD, ALD, and/or are formed using another deposition technique.

FIG. 3B illustrates a perspective view of the semiconductor device 200 and a cross-sectional view along the line A-A. As shown in FIG. 3B, the layer stack 305 and the semiconductor substrate 205 are etched to remove portions of the layer stack 305 and portions of the semiconductor substrate 205. The portions 340 of the layer stack 305, and mesa regions 210 (also referred to as silicon mesas or mesa portions), remaining after the etch operation are referred to as fin structures 345 above the semiconductor substrate 205 of the semiconductor device 200. A fin structure 345 includes a portion 340 of the layer stack 305 over and/or on a mesa region 210 formed in and/or above the semiconductor substrate 205. The fin structures 345 may be formed by any suitable semiconductor processing technique. For example, the deposition tool 102, the exposure tool 104, the developer tool 106, and/or the etch tool 108 may form the fin structures 345 using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

In some implementations, the deposition tool 102 forms a photoresist layer over and/or on the hard mask layer including the oxide layer 330 and the nitride layer 335, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking element (or pattern) in the photoresist layer. In some implementations, patterning the photoresist layer to form the masking element is performed using an electron beam (e-beam) lithography process. The masking element may then be used to protect portions of the semiconductor substrate 205 and portions the layer stack 305 in an etch operation such that the portions of the semiconductor substrate 205 and portions the layer stack 305 remain non-etched to form the fin structures 345. Unprotected portions of the substrate and unprotected portions of the layer stack 305 are etched (e.g., by the etch tool 108) to form trenches in the semiconductor substrate 205. The etch tool may etch the unprotected portions of the substrate and unprotected portions of the layer stack 305 using a dry etch technique (e.g., reactive ion etching), a wet etch technique, and/or a combination thereof.

In some implementations, another fin formation technique is used to form the fin structures 345. For example, a fin region may be defined (e.g., by mask or isolation regions), and the portions 340 may be epitaxially grown in the form of the fin structures 345. In some implementations, forming the fin structures 345 includes a trim process to decrease the width of the fin structures 345. The trim process may include wet and/or dry etching processes, among other examples.

As further shown in FIG. 3B, fin structures 345 may be formed for different types of nanostructure transistors for the semiconductor device 200. In particular, a first subset of fin structures 345a may be formed for p-type nanostructure transistors (e.g., p-type metal oxide semiconductor (PMOS) nanostructure transistors), and a second subset of fin structures 345b may be formed for n-type nanostructure transistors (e.g., n-type metal oxide semiconductor (NMOS) nanostructure transistors). The second subset of fin structures 345b may be doped with a p-type dopant (e.g., boron (B) and/or germanium (Ge), among other examples) and the first subset of fin structures 345a may be doped with an n-type dopant (e.g., phosphorous (P) and/or arsenic (As), among other examples). Additionally or alternatively, p-type source/drain regions may be subsequently formed for the p-type nanostructure transistors that include the first subset of fin structures 345a, and n-type source/drain regions may be subsequently formed for the n-type nanostructure transistors that include the second subset of fin structures 345b.

The first subset of fin structures 345a (e.g., PMOS fin structures) and the second subset of fin structures 345b (e.g., NMOS fin structures) may be formed to include similar properties and/or different properties. For example, the first subset of fin structures 345a may be formed to a first height and the second subset of fin structures 345b may be formed to a second height, where the first height and the second height are different heights. As another example, the first subset of fin structures 345a may be formed to a first width and the second subset of fin structures 345b may be formed to a second width, where the first width and the second width are different widths. In the example shown in FIG. 3B, the second width of the second subset of fin structures 345b (e.g., for the NMOS nanostructure transistors) is greater relative to the first width of the first subset of fin structures 345a (e.g., for the PMOS nanostructure transistors). However, other examples are within the scope of the present disclosure.

As indicated above, FIGS. 3A and 3B are provided as an example. Other examples may differ from what is described with regard to FIGS. 3A and 3B. Example implementation 300 may include additional operations, fewer operations, different operations, and/or a different order of operations than those described in connection with FIGS. 3A and 3B.

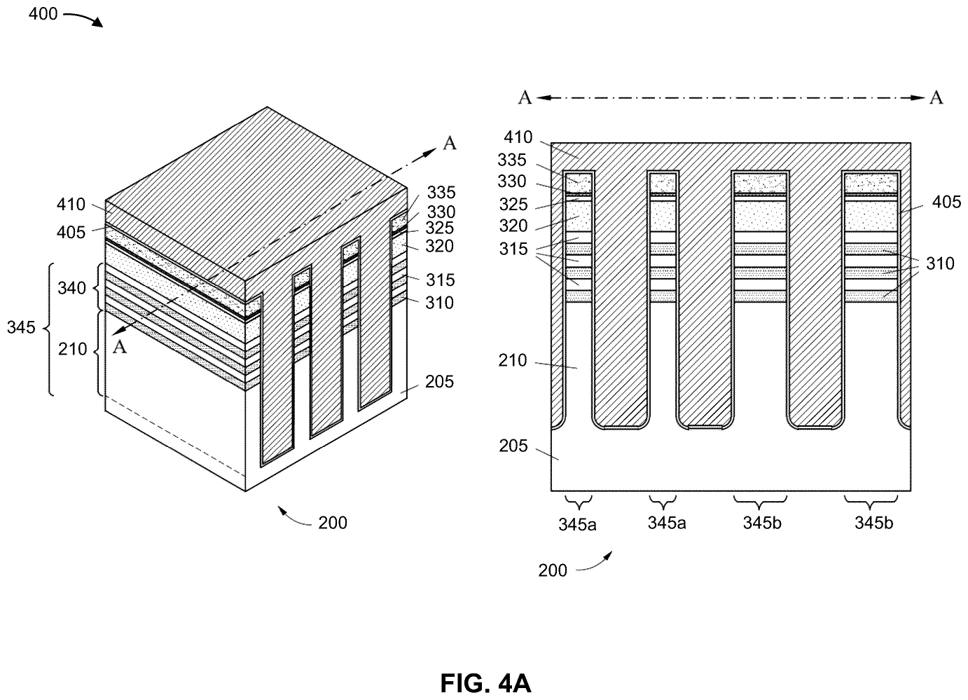

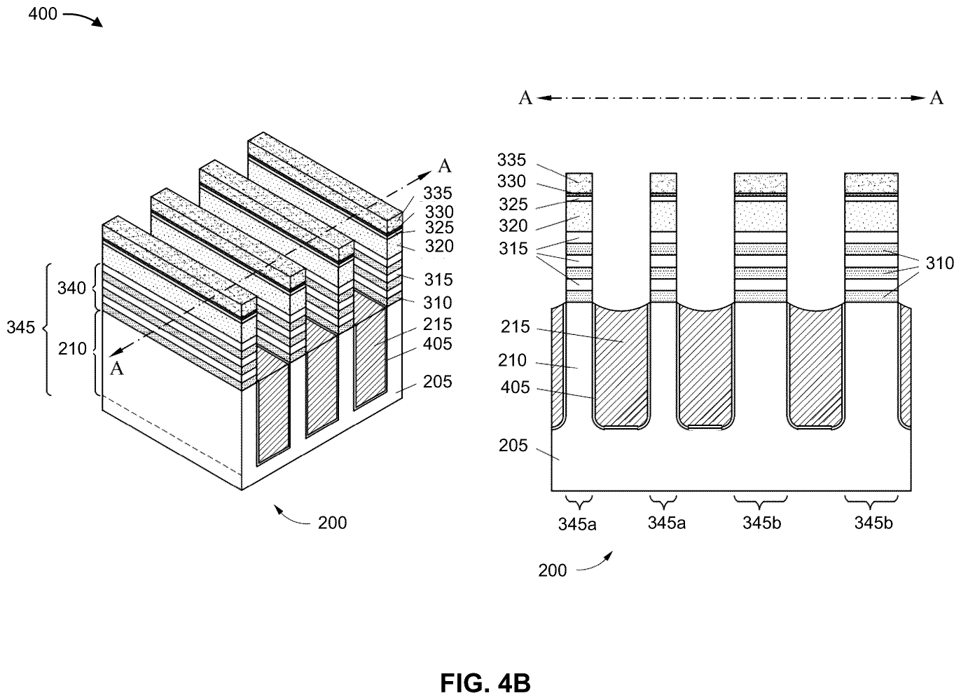

FIGS. 4A and 4B are diagrams of an example implementation 400 of an STI formation process described herein. The example implementation 400 includes an example of forming STI regions 215 between the fin structures 345 for the semiconductor device 200 or a portion thereof. The semiconductor device 200 may include one or more additional devices, structures, and/or layers not shown in FIGS. 4A and/or 4B. The semiconductor device 200 may include additional layers and/or dies formed on layers above and/or below the portion of the semiconductor device 200 shown in FIGS. 4A and 4B. Additionally, or alternatively, one or more additional semiconductor structures and/or semiconductor devices may be formed in a same layer of an electronic device that includes the semiconductor device 200. In some implementations, the operations described in connection with the example implementation 400 are performed after the processes described in connection with FIGS. 3A and 3B.

FIG. 4A illustrates a perspective view of the semiconductor device 200 and a cross-sectional view along the line A-A. As shown in FIG. 4A, a liner 405 and a dielectric layer 410 are formed above the semiconductor substrate 205 and interposing (e.g., in between) the fin structures 345. The deposition tool 102 may deposit the liner 405 and the dielectric layer 410 over the semiconductor substrate 205 and in the trenches between the fin structures 345. The deposition tool 102 may form the dielectric layer 410 such that a height of a top surface of the dielectric layer 410 and a height of a top surface of the nitride layer 335 are approximately a same height.

Alternatively, the deposition tool 102 may form the dielectric layer 410 such that the height of the top surface of the dielectric layer 410 is greater relative to the height of the top surface of the nitride layer 335, as shown in FIG. 4A. In this way, the trenches between the fin structures 345 are overfilled with the dielectric layer 410 to ensure that the trenches are fully filled with the dielectric layer 410. Subsequently, the planarization tool 110 may perform a planarization or polishing operation (e.g., a CMP operation) to planarize the dielectric layer 410. The nitride layer 335 of the hard mask layer may function as a CMP stop layer in the operation. In other words, the planarization tool 110 planarizes the dielectric layer 410 until reaching the nitride layer 335 of the hard mask layer. Accordingly, a height of top surfaces of the dielectric layer 410 and a height of top surfaces of the nitride layer 335 are approximately equal after the operation.

The deposition tool 102 may deposit the liner 405 using a conformal deposition technique. The deposition tool 102 may deposit the dielectric layer using a CVD technique (e.g., a flowable CVD (FCVD) technique or another CVD technique), a PVD technique, an ALD technique, and/or another deposition technique. In some implementations, after deposition of the liner 405, the semiconductor device 200 is annealed, for example, to increase the quality of the liner 405.

The liner 405 and the dielectric layer 410 each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. In some implementations, the dielectric layer 410 may include a multi-layer structure, for example, having one or more liner layers.

FIG. 4B illustrates a perspective view of the semiconductor device 200 and a cross-sectional view along the line A-A. As shown in FIG. 4B, an etch back operation is performed to remove portions of the liner 405 and portions of the dielectric layer 410 to form the STI regions 215. The etch tool 108 may etch the liner 405 and the dielectric layer 410 in the etch back operation to form the STI regions 215. The etch tool 108 etches the liner 405 and the dielectric layer 410 based on the hard mask layer (e.g., the hard mask layer including the oxide layer 330 and the nitride layer 335). The etch tool 108 etches the liner 405 and the dielectric layer 410 such that the heights of the STI regions 215 are less than or approximately a same height as the bottom of the portions 340 of the layer stack 305. Accordingly, the portions 340 of the layer stack 305 extend above the STI regions 215. In some implementations, the liner 405 and the dielectric layer 410 are etched such that the heights of the STI regions 215 are less than heights of top surfaces of the mesa regions 210.

In some implementations, the etch tool 108 uses a dry etch technique to etch the liner 405 and the dielectric layer 410. Ammonia (NH₃), hydrofluoric acid (HF), and/or another etchant may be used. The plasma-based dry etch technique may result in a reaction between the etchant(s) and the material of the liner 405 and the dielectric layer 410, including:

SiO₂+4HF→SiF₄+2H₂O

where silicon dioxide (SiO₂) of the liner 405 and the dielectric layer 410 react with hydrofluoric acid to form byproducts including silicon tetrafluoride (SiF₄) and water (H₂O). The silicon tetrafluoride is further broken down by the hydrofluoric acid and ammonia to form an ammonium fluorosilicate ((NH₄)₂SiF₆) byproduct:

SiF₄+2HF+2NH₃→(NH₄)₂SiF₆

The ammonium fluorosilicate byproduct is removed from a processing chamber of the etch tool 108. After removal of the ammonium fluorosilicate, a post-process temperature in a range of approximately 100 degrees Celsius to approximately 250 degrees Celsius is used to sublimate the ammonium fluorosilicate into constituents of silicon tetrafluoride ammonia and hydrofluoric acid.

In some implementations, the etch tool 108 etches the liner 405 and the dielectric layer 410 such that a height of the STI regions 215 between the first subset of fin structures 345a (e.g., for the PMOS nanostructure transistors) is greater than a height of the STI regions 215 between the second subset of fin structures 345b (e.g., for the NMOS nanostructure transistors). This primarily occurs due to the greater width of the fin structures 345b relative to the width of the fin structures 345a. Moreover, this results in a top surface of an STI region 215 between a fin structure 345a and a fin structure 345b being sloped or slanted (e.g., downward sloped from the fin structure 345a to the fin structure 345b, as shown in the example in FIG. 4A). The etchants used to etch the liner 405 and the dielectric layer 410 first experience physisorption (e.g., a physical bonding to the liner 405 and the dielectric layer 410) as a result of a Van der Waals force between the etchants and the surfaces of the liner 405 and the dielectric layer 410. The etchants become trapped by dipole movement force. The etchants then attach to dangling bonds of the liner 405 and the dielectric layer 410, and chemisorption begins. Here, the chemisorption of the etchant on the surface of the liner 405 and the dielectric layer 410 results in etching of the liner 405 and the dielectric layer 410. The greater width of the trenches between the second subset of fin structures 345b provides a greater surface area for chemisorption to occur, which results in a greater etch rate between the second subset of fin structures 345b. The greater etch rate results in the height of the STI regions 215 between the second subset of fin structures 345b being less than the height of the STI regions 215 between the first subset of fin structures 345a.

As indicated above, FIGS. 4A and 4B are provided as an example. Other examples may differ from what is described with regard to FIGS. 4A and 4B. Example implementation 400 may include additional operations, fewer operations, different operations, and/or a different order of operations than those described in connection with FIGS. 4A and 4B.

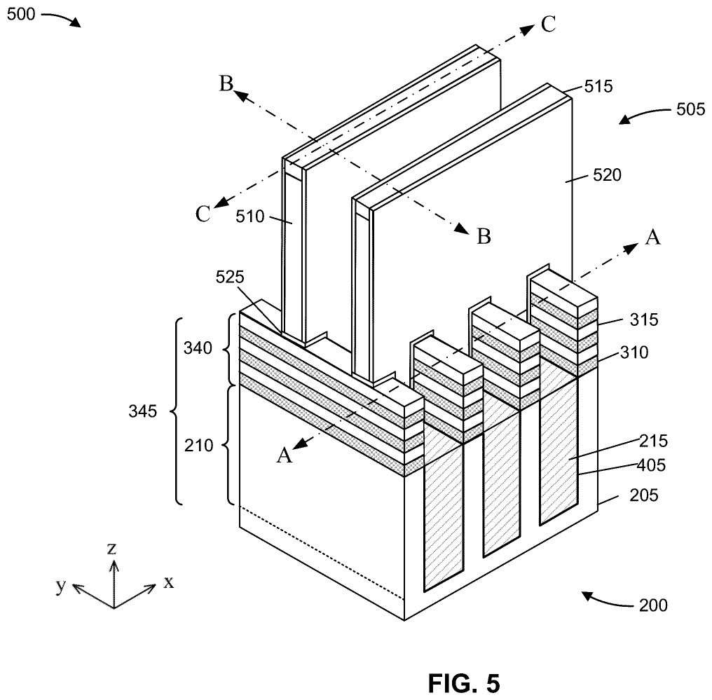

FIG. 5 is a diagram of an example implementation 500 of a dummy gate formation process described herein. The example implementation 500 includes an example of forming dummy gate structures for the semiconductor device 200 or a portion thereof. The semiconductor device 200 may include one or more additional devices, structures, and/or layers not shown in FIG. 5. The semiconductor device 200 may include additional layers and/or dies formed on layers above and/or below the portion of the semiconductor device 200 shown in FIG. 5. Additionally, or alternatively, one or more additional semiconductor structures and/or semiconductor devices may be formed in a same layer of an electronic device that includes the semiconductor device 200. In some implementations, the operations described in connection with the example implementation 500 are performed after the processes described in connection with FIGS. 3A-4B.

FIG. 5 illustrates a perspective view of the semiconductor device 200. As shown in FIG. 5, dummy gate structures 505 (also referred to as dummy gate stacks or temporary gate structures) are formed over the fin structures 345. The dummy gate structures 505 are sacrificial structures that are to be replaced by replacement gate structures or replacement gate stacks (e.g., the gate structures 240) at a subsequent processing stage for the semiconductor device 200. Portions of the fin structures 345 underlying the dummy gate structures 505 may be referred to as channel regions. The dummy gate structures 505 may also define source/drain (S/D) regions of the fin structures 345, such as the regions of the fin structures 345 adjacent and on opposing sides of the channel regions.

A dummy gate structure 505 may include a gate electrode layer 510, a hard mask layer 515 over and/or on the gate electrode layer 510, and spacer layers 520 on opposing sides of the gate electrode layer 510 and on opposing sides of the hard mask layer 515. The dummy gate structures 505 may be formed on a gate dielectric layer 525 between the top-most second layer 315 and the dummy gate structures 505. The gate electrode layer 510 includes polycrystalline silicon (polysilicon or PO) or another material. The hard mask layer 515 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 520 include a silicon oxycarbide (SiOC), a nitrogen free SiOC, or another suitable material. The gate dielectric layer 525 may include a silicon oxide (e.g., SiOₓ such as SiO₂), a silicon nitride (e.g., SiₓN_{y} such as Si₃N₄), a high-K dielectric material and/or another suitable material.

The layers of the dummy gate structures 505 may be formed using various semiconductor processing techniques such as deposition (e.g., by the deposition tool 102), patterning (e.g., by the exposure tool 104 and the developer tool 106), and/or etching (e.g., by the etch tool 108), among other examples. Examples include CVD, PVD, ALD, thermal oxidation, e-beam evaporation, photolithography, e-beam lithography, photoresist coating (e.g., spin coating), soft baking, mask aligning, exposure, post-exposure baking, photoresist developing, rinsing, drying (e.g., spin drying and/or hard baking), dry etching (e.g., reactive ion etching), and/or wet etching, among other examples.

In some implementations, the gate dielectric layer 525 is conformally deposited on the semiconductor device 200 and then selectively removed from portions of the semiconductor device 200 (e.g., the source/drain areas). The gate electrode layer 510 is then deposited onto the remaining portions of the gate dielectric layer 525. The hard mask layers 515 are then deposited onto the gate electrode layers 510. The spacer layers 520 may be conformally deposited in a similar manner as the gate dielectric layer 525 and etched back such that the spacer layers 520 remain on the sidewalls of the dummy gate structures 505. In some implementations, the spacer layers 520 include a plurality of types of spacer layers. For example, the spacer layers 520 may include a seal spacer layer that is formed on the sidewalls of the dummy gate structures 505 and a bulk spacer layer that is formed on the seal spacer layer. The seal spacer layer and the bulk spacer layer may be formed of similar materials or different materials. In some implementations, the bulk spacer layer is formed without a plasma surface treatment that is used for the seal spacer layer. In some implementations, the bulk spacer layer is formed to a greater thickness than the thickness of the seal spacer layer. In some implementations, the gate dielectric layer 525 is omitted from the dummy gate structure formation process and is instead formed in the replacement gate process.

FIG. 5 illustrates reference cross-sections that are used in subsequent figures described herein. Cross-section A-A is in an x-z plane (referred to as a y-cut) across the fin structures 345 in source/drain areas of the semiconductor device 200. Cross-section B-B is in a y-z plane (referred to as an x-cut) perpendicular to the cross-section A-A, and is across the dummy gate structures 505 in the source/drain areas of the semiconductor device 200. Cross-section C-C is in the x-z plane parallel to the cross-section A-A and perpendicular to the cross-section B-B, and is along a dummy gate structure 505. Subsequent figures refer to these reference cross-sections for clarity. In some figures, some reference numbers of components or features illustrated therein may be omitted to avoid obscuring other components or features for ease of depicting the figures.

As indicated above, FIG. 5 is provided as an example. Other examples may differ from what is described with regard to FIG. 5. Example implementation 500 may include additional operations, fewer operations, different operations, and/or a different order of operations than those described in connection with FIG. 5.

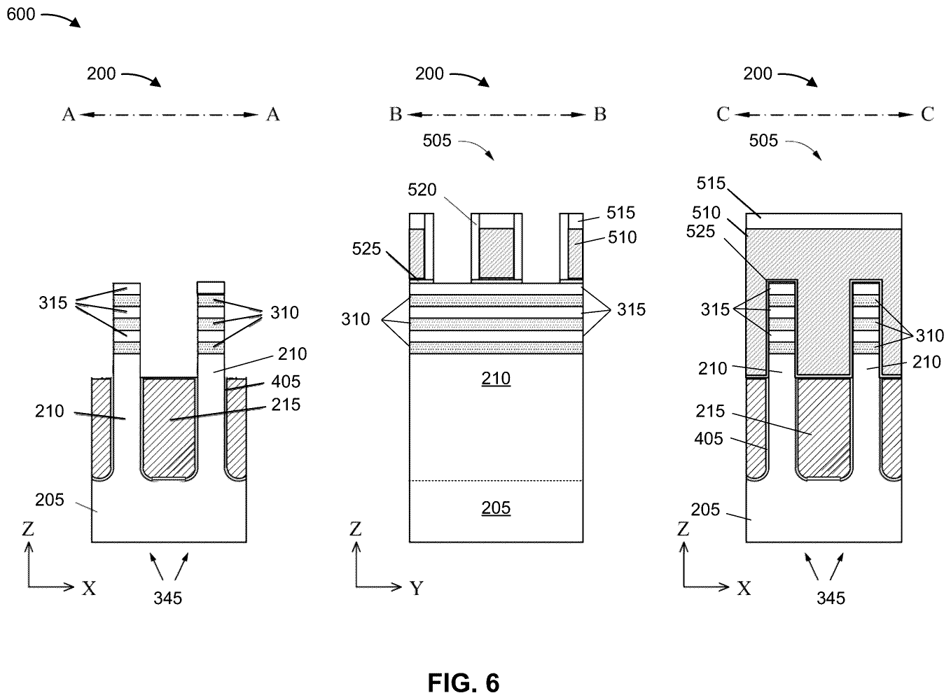

FIG. 6 is a diagram of an example implementation 600 of the semiconductor device 200 described herein. FIG. 6 includes cross-sectional views along the cross-sectional planes A-A, B-B, and C-C of FIG. 5. As shown in the cross-sectional planes B-B and C-C in FIG. 6, the dummy gate structures 505 are formed above the fin structures 345. As shown in the cross-sectional plane C-C in FIG. 6, portions of the gate dielectric layer 525 and portions of the gate electrode layers 510 are formed in recesses above the fin structures 345 that are formed as a result of the removal of the hard mask layer 320.

As indicated above, FIG. 6 is provided as an example. Other examples may differ from what is described with regard to FIG. 6. Example implementation 600 may include additional operations, fewer operations, different operations, and/or a different order of operations than those described in connection with FIG. 6.

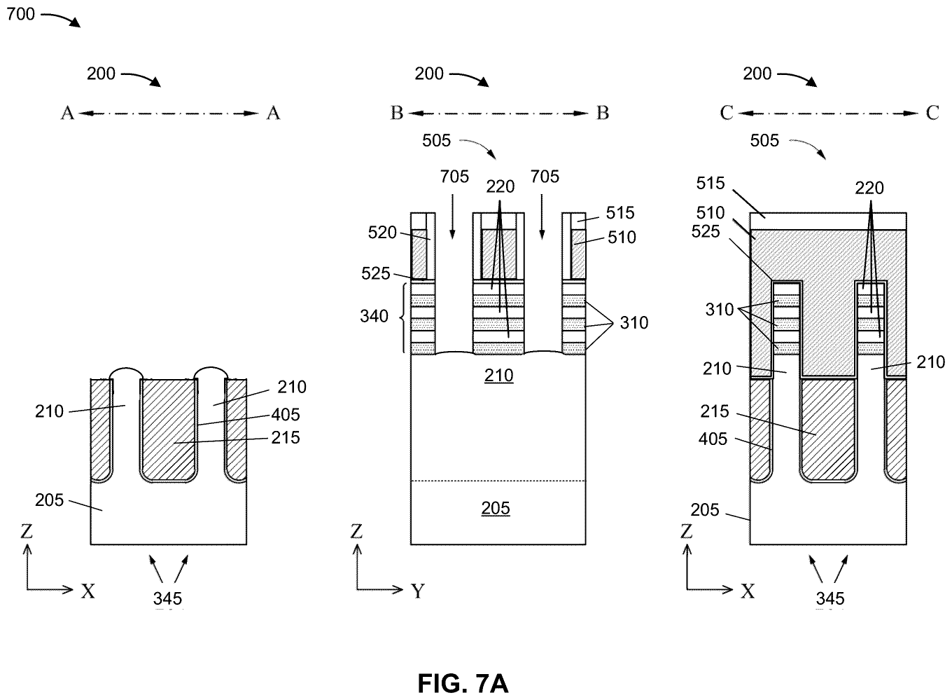

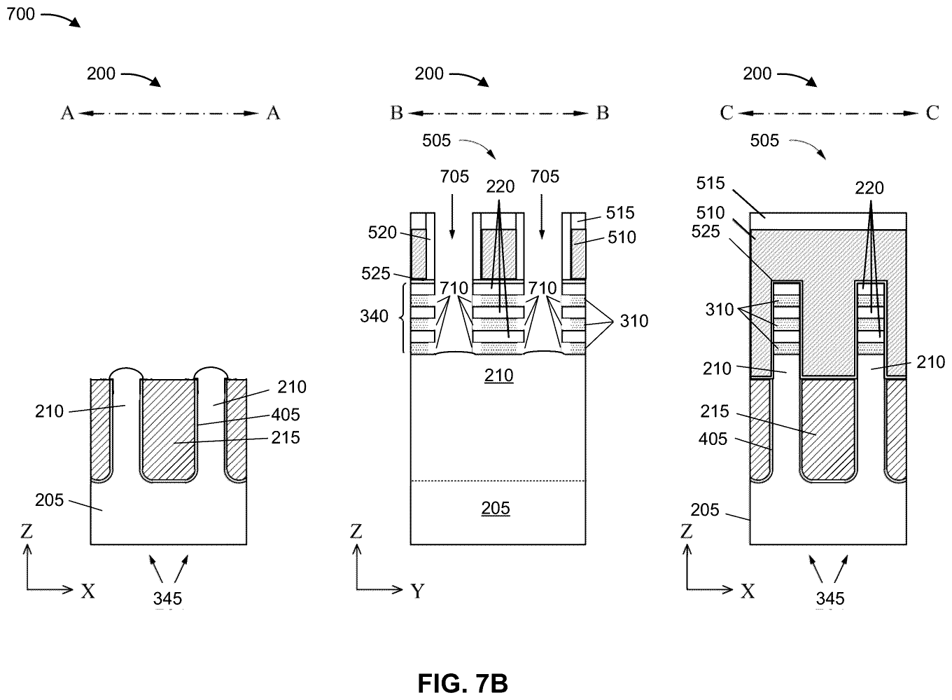

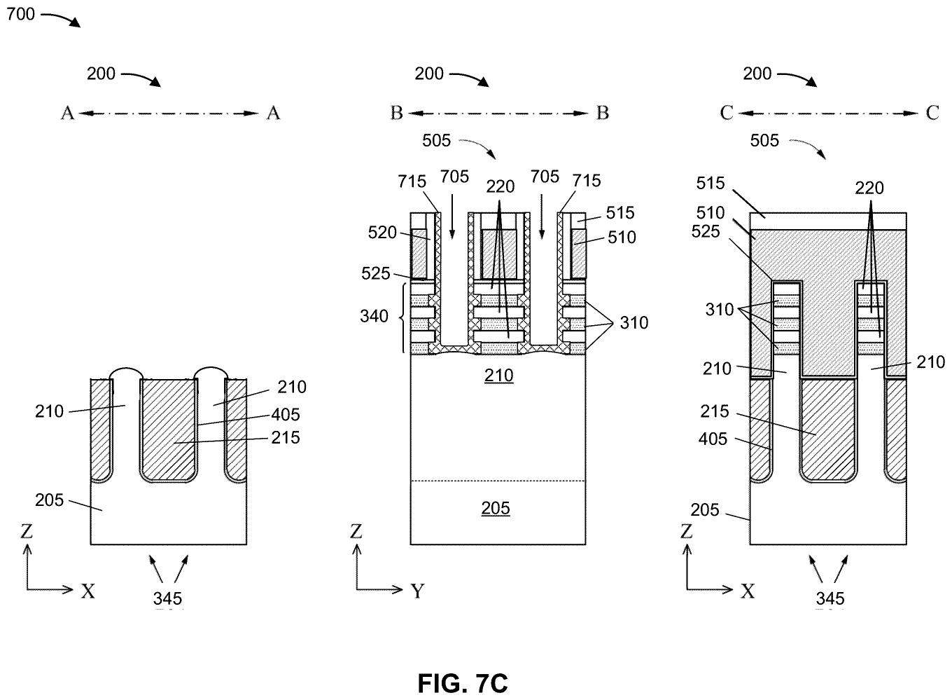

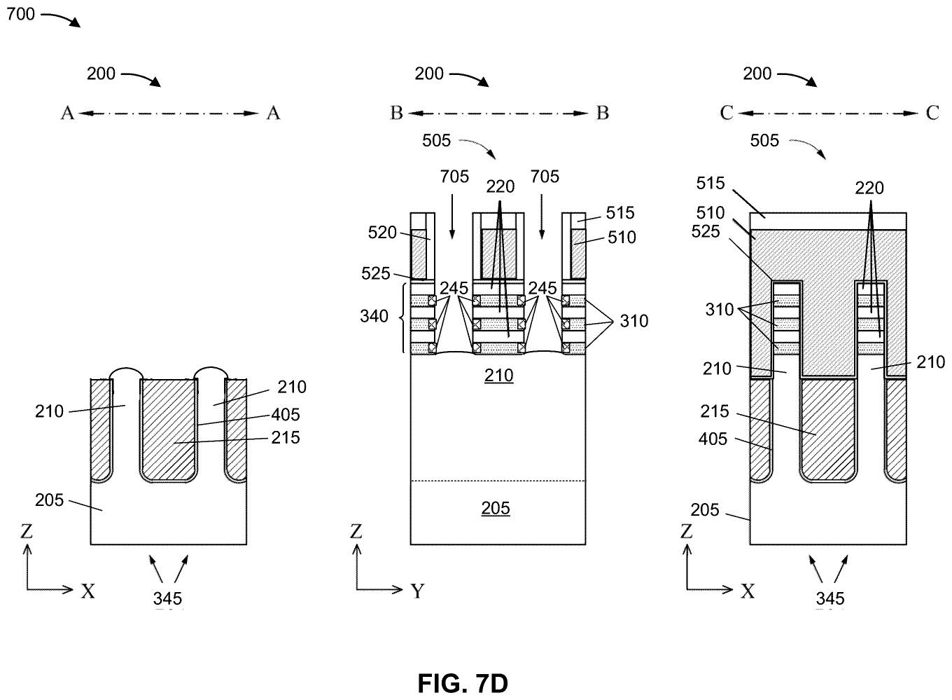

FIGS. 7A-7D are diagrams of an example implementation 700 of a source/drain recess formation process and an inner spacer formation process described herein. The example implementation 700 includes an example of forming source/drain recesses and the inner spacers 245 for the semiconductor device 200. FIGS. 7A-7D are illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 700 are performed after the processes described in connection with FIGS. 3A-6.

As shown in the cross-sectional plane A-A and cross-sectional plane B-B in FIG. 7A source/drain recesses 705 are formed in the portions 340 of the fin structure 345 in an etch operation. The source/drain recesses 705 are formed to provide spaces in which source/drain regions 225 are to be formed on opposing sides of the dummy gate structures 505. The etch operation may be performed by the etch tool 108 and may be referred to a strained source/drain (SSD) etch operation. In some implementations, the etch operation includes a plasma etch technique, a wet chemical etch technique, and/or another type of etch technique.

In some implementations, the source/drain recesses 705 also extend into a portion of the mesa regions 210 of the fin structure 345. In these implementations, the source/drain recesses 705 may penetrate into a well portion (e.g., a p-well, an n-well) of the fin structure 345. In implementations in which the semiconductor substrate 205 includes a silicon (Si) material having a (100) orientation, (111) faces are formed at bottoms of the source/drain recesses 705, resulting in formation of a V-shape or a triangular shape cross section at the bottoms of the source/drain recesses 705. In some implementations, a wet etching using tetramethylammonium hydroxide (TMAH) and/or a chemical dry etching using hydrochloric acid (HCl) are employed to form the V-shape profile. However, the cross section at the bottoms of the source/drain recesses 705 may include other shapes, such as round or semi-circular, among other examples.

As shown in the cross-sectional plane B-B and the cross-sectional plane C-C in FIG. 5, portions of the first layers 310 and portions of the second layers 315 of the layer stack 305 remain under the dummy gate structures 505 after the etch operation to form the source/drain recesses 705. The portions of the second layers 315 under the dummy gate structures 505 form the nanostructure channels 220 of the nanostructure transistors of the semiconductor device 200. The nanostructure channels 220 extend between adjacent source/drain recesses 705.

As shown in the cross-sectional plane B-B in FIG. 7B, the first layers 310 are laterally etched (e.g., in a direction that is approximately parallel to a length of the first layers 310) in an etch operation, thereby forming cavities 710 between portions of the nanostructure channels 220. In particular, the etch tool 108 laterally etches ends of the first layers 310 under the dummy gate structures 505 through the source/drain recesses 705 to form the cavities 710 between ends of the nanostructure channels 220. In implementations where the first layers 310 are silicon germanium (SiGe) and the second layers 315 are silicon (Si), the etch tool 108 may selectively etch the first layers 310 using a wet etchant, such as a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 705 to etch the first layers 310 from the source/drain recesses 705. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 60° Celsius to approximately 90° Celsius. However, other values for the parameters of the etch operation are within the scope of the present disclosure.

The cavities 710 may be formed to an approximately curved shape, an approximately concave shape, an approximately triangular shape, an approximately square shape, or to another shape. In some implementations, the depth of one or more of the cavities 710 (e.g., the dimension of the cavities extending into the first layers 310 from the source/drain recesses 705) is in a range of approximately 0.5 nanometers to about 5 nanometers. In some implementations, the depth of one or more of the cavities 710 is in a range of approximately 1 nanometer to approximately 3 nanometers. However, other values for the depth of the cavities 710 are within the scope of the present disclosure. In some implementations, the etch tool 108 forms the cavities 710 to a length (e.g., the dimension of the cavities extending from a nanostructure channel 220 below a first layer 310 to another nanostructure channel 220 above the first layer 310) such that the cavities 710 partially extend into the sides of the nanostructure channels 220 (e.g., such that the widths or lengths of the cavities 710 are greater than the thickness of the first layers 310). In this way, the inner spacers that are to be formed in the cavities 710 may extend into a portion of the ends of the nanostructure channels 220.

As shown in the cross-sectional plane A-A and in the cross-sectional plane B-B in FIG. 7C, an insulating layer 715 is conformally deposited along the bottom and along the sidewalls of the source/drain recesses 705. The insulating layer 715 further extends along the spacer layer 520. The deposition tool 102 may deposit the insulating layer 715 using a CVD technique, a PVD technique, an ALD technique, and/or another deposition technique. The insulating layer 715 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material. The insulating layer 715 may include a material that is different from the material of spacer layers 520.

The deposition tool 102 forms the insulating layer 715 to a thickness sufficient to fill in the cavities 710 between the nanostructure channels 220 with the insulating layer 715. For example, the insulating layer 715 may be formed to a thickness in a range of approximately 1 nanometer to approximately 10 nanometers. As another example, the insulating layer 715 may be formed to a thickness in a range of approximately 2 nanometers to approximately 5 nanometers. However, other values for the thickness of the insulating layer 715 are within the scope of the present disclosure.

As shown in the cross-sectional plane A-A and in the cross-sectional plane B-B in FIG. 7D, the insulating layer 715 is partially removed such that remaining portions of the insulating layer 715 correspond to the inner spacers 245 in the cavities 710. The etch tool 108 may perform an etch operation to partially remove the insulating layer 715.

In some implementations, the etch operation may result in the surfaces of the inner spacers 245 facing the source/drain recesses 705 being curved or recessed. The depth of the recesses in the inner spacers 245 may be in a range of approximately 0.2 nanometers to approximately 3 nanometers. As another example, the depth of the recesses in the inner spacers 245 may be in a range of approximately 0.5 nanometers to approximately 2 nanometers. As another example, the depth of the recesses in the inner spacers 245 may be in a range of less than approximately 0.5 nanometers. In some implementations, the surfaces of the inner spacers 245 facing the source/drain recesses 705 are approximately flat such that the surfaces of the inner spacers 245 and the surfaces of the ends of the nanostructure channels 220 are approximately even and flush.

As indicated above, FIGS. 7A-7D are provided as examples. Other examples may differ from what is described with regard to FIGS. 7A-7D. Example implementation 700 may include additional operations, fewer operations, different operations, and/or a different order of operations than those described in connection with FIGS. 7A-7D.

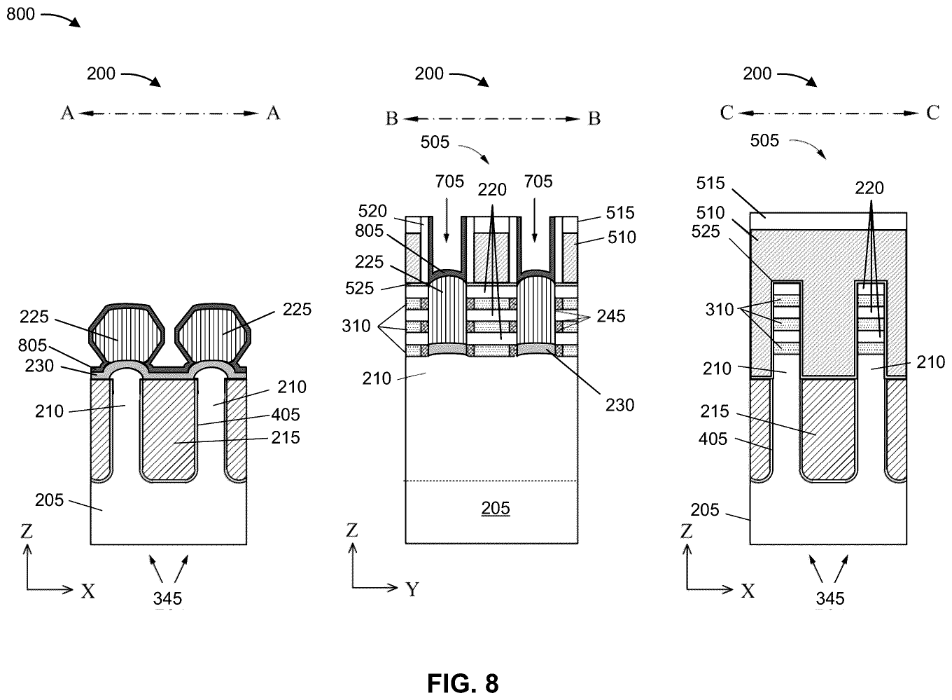

FIG. 8 is a diagram of an example implementation 800 of a source/drain region formation process described herein. The example implementation 800 includes an example of forming the source/drain regions 225 in the source/drain recesses 705 for the semiconductor device 200.

FIG. 8 is illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 800 are performed after the processes described in connection with FIGS. 3A-7D.

As shown in the cross-sectional plane B-B and the cross-sectional plane B-B in FIG. 8, the source/drain recesses 705 are filled with one or more layers to form the source/drain regions 225 in the source/drain recesses 705. For example, the deposition tool 102 may deposit a buffer region 230 at the bottom of the source/drain recesses 705, the deposition tool 102 may deposit the source/drain regions 225 on the buffer region 230, and the deposition tool 102 may deposit a contact etch stop layer (CESL) 805 on the source/drain regions 225. In some implementations, a capping layer 235 (not shown) is deposited on the source/drain regions 225 prior to forming the CESL 805.

The buffer region 230 may include silicon (Si), silicon doped with boron (SiB) or another dopant, and/or another material. The buffer region 230 may be included to reduce, minimize, and/or prevent dopant migration and/or current leakage from the source/drain regions 225 into the mesa regions 210, which might otherwise cause short channel effects in the semiconductor device 200. Accordingly, the buffer region 230 may increase the performance of the semiconductor device 200 and/or increase yield of the semiconductor device 200. In some implementations, the buffer region 230 is omitted from one or more of the source/drain regions 225.

The source/drain regions 225 may include one or more layers of epitaxially grown material. For example, the deposition tool 102 may epitaxially grow a first layer of the source/drain regions 225 (referred to as an L1) over the buffer region 230, and may epitaxially grow a second layer of the source/drain regions 225 (referred to as an L2, an L2-1, and/or an L2-2) over the first layer.

In some implementations, p-type source/drain regions are formed for a PMOS nanostructure transistor (e.g., a PMOS field effect transistor (PFET)) of the semiconductor device 200, and n-type source/drain regions are formed for an NMOS nanostructure transistor (e.g., an NMOS field effect transistor (NFET)) of the semiconductor device 200. The p-type source/drain regions may include a semiconductor material (e.g., silicon (Si), silicon germanium (SiGe)) doped with a p-type dopant such as boron (B) (e.g., boron-doped silicon (SiB) and/or boron-doped silicon germanium (SiGeB), among other examples). Additionally and/or alternatively, the p-type source/drain regions may include silicon germanium (SiGe). The n-type source/drain regions may include undoped silicon (Si) and/or silicon doped with an n-type dopant such as phosphorous (P) (e.g., phosphorous-doped silicon (SiP)) and/or arsenic (As) (arsenic-doped silicon (SiAs)), among other examples.

In some implementations, the CESL 805 is conformally deposited (e.g., using the deposition tool 102) over the source/drain regions 225 prior to formation of the ILD layer 250. The ILD layer 250 is then formed on the CESL 805. The CESL 805 may provide a mechanism to stop an etch process when forming contacts or vias for the source/drain regions 225. The CESL 805 may be formed of a dielectric material having a different etch selectivity from adjacent layers or components. The CESL 805 may include or may be a nitrogen-containing material, a silicon-containing material, and/or a carbon-containing material. Furthermore, the CESL 805 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 805 may be deposited using a deposition technique such as ALD, CVD, or another deposition technique.

As indicated above, FIG. 8 is provided as an example. Other examples may differ from what is described with regard to FIG. 8. Example implementation 800 may include additional operations, fewer operations, different operations, and/or a different order of operations than those described in connection with FIG. 8.

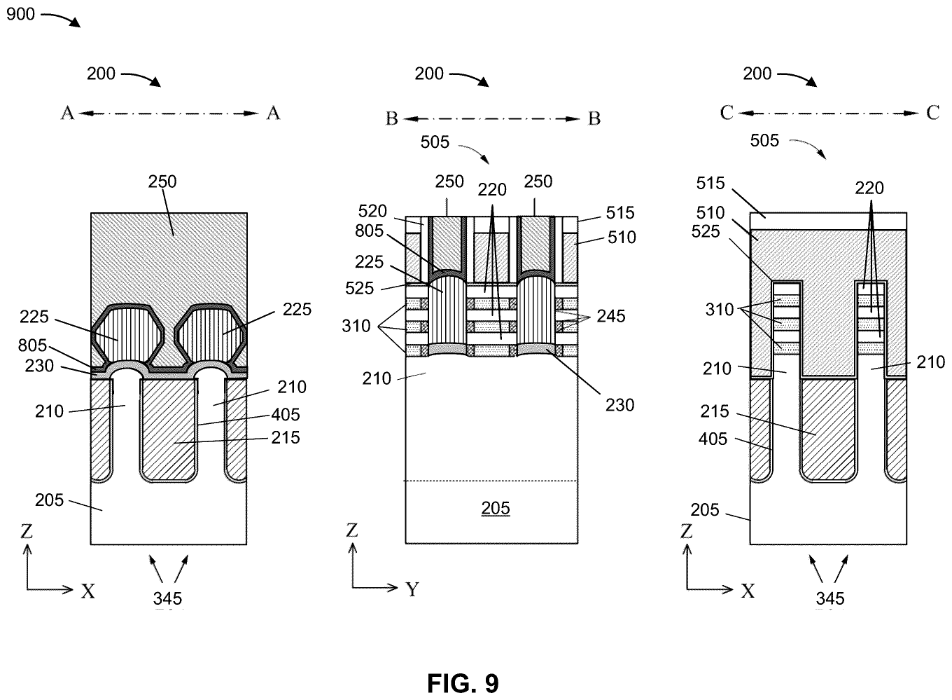

FIG. 9 is a diagram of an example implementation 900 of an ILD formation process described herein. FIG. 9 is illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 900 are performed after the operations described in connection with FIGS. 3A-8.

As shown in the cross-sectional plane A-A and the cross-sectional plane B-B in FIG. 9, the ILD layer 250 is formed over the source/drain regions 225. In particular, the ILD layer 250 may be formed on the CESL 805 that is over the source/drain regions 225. The ILD layer 250 fills in areas between the dummy gate structures 505, and the areas above the source/drain regions 225. The ILD layer 250 is formed to reduce the likelihood of and/or prevent damage to the source/drain regions 225 during the replacement gate process. The ILD layer 250 may be referred to as an ILD zero (ILDO) layer or another ILD layer.

A deposition tool 102 may be used to deposit the ILD layer 250 using a PVD technique, an ALD technique, a CVD technique, an oxidation technique, another type of deposition technique described in connection with FIG. 1, and/or another suitable deposition technique. The ILD layer 250 may be deposited in one or more deposition operations. In some implementations, a planarization tool 110 may be used to planarize the ILD layer 250 after the ILD layer 250 is deposited.

As indicated above, the number and arrangement of operations and devices shown in FIG. 9 are provided as one or more examples. In practice, there may be additional operations and devices, fewer operations and devices, different operations and devices, or differently arranged operations and devices than those shown in FIG. 9.

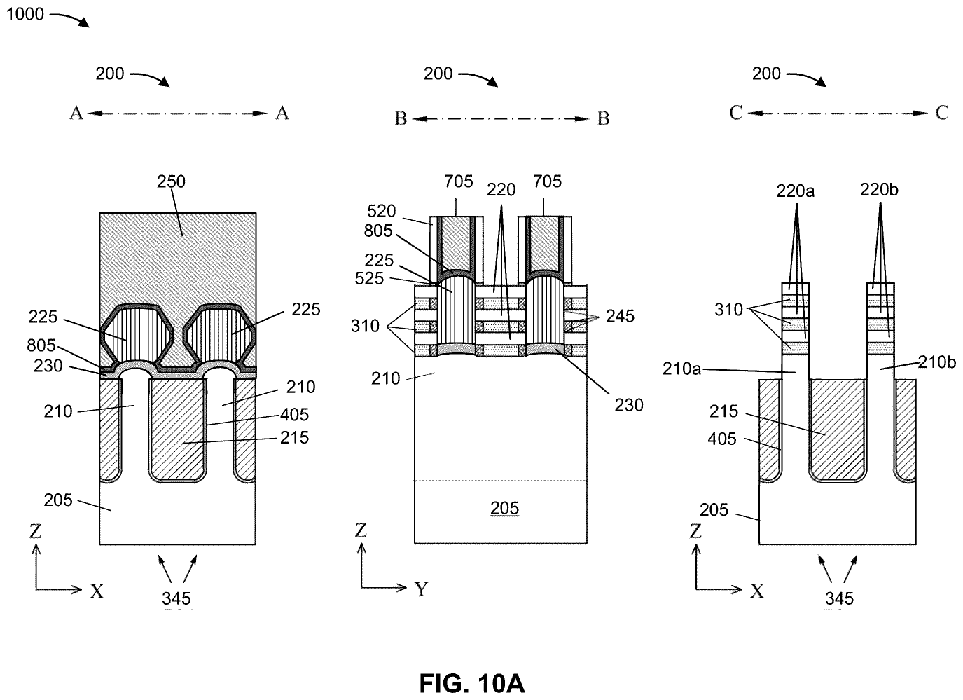

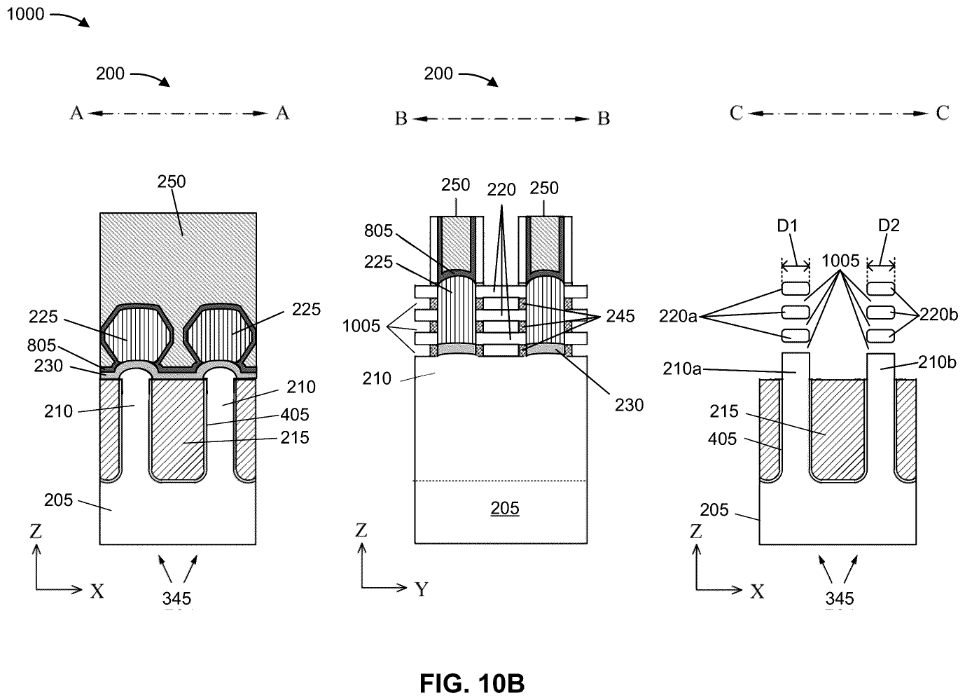

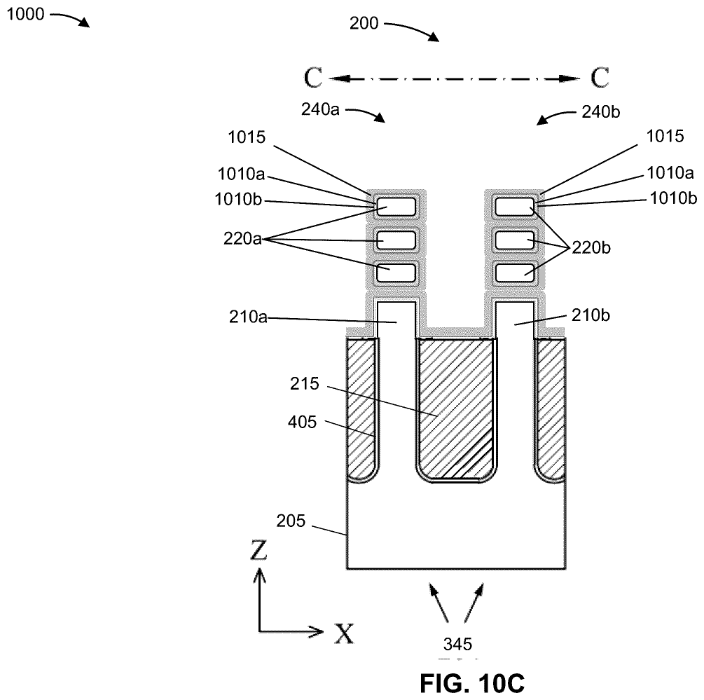

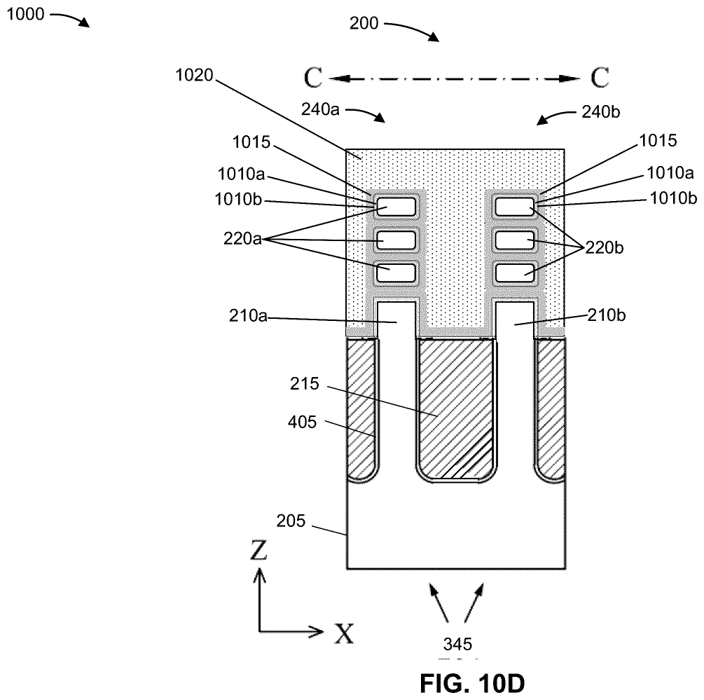

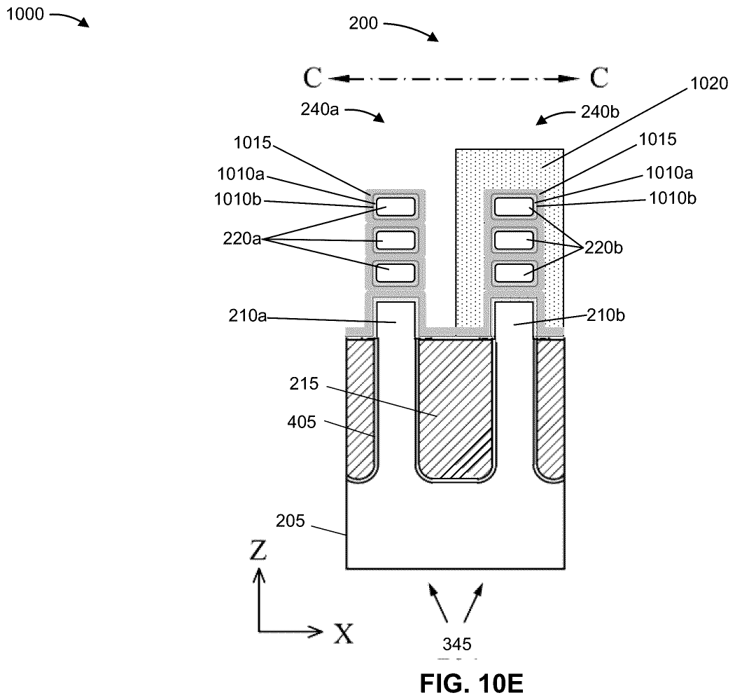

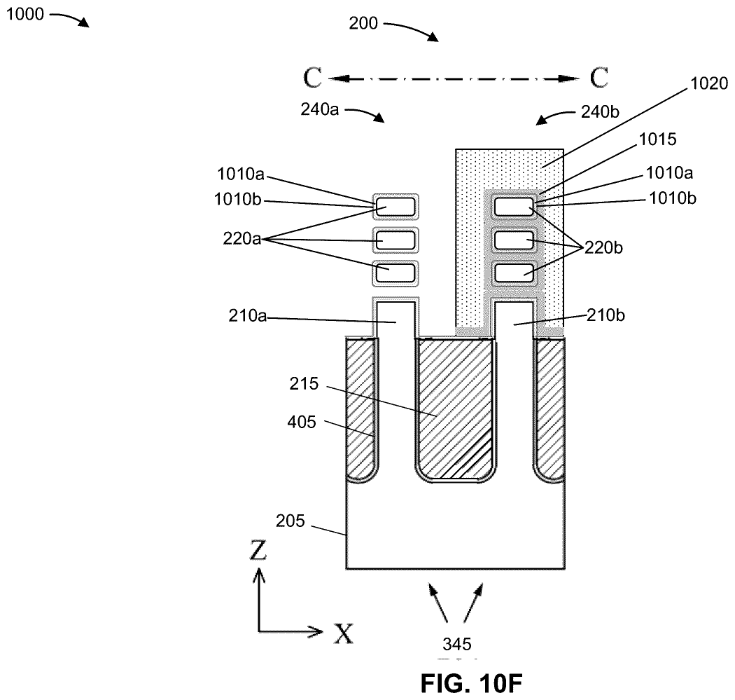

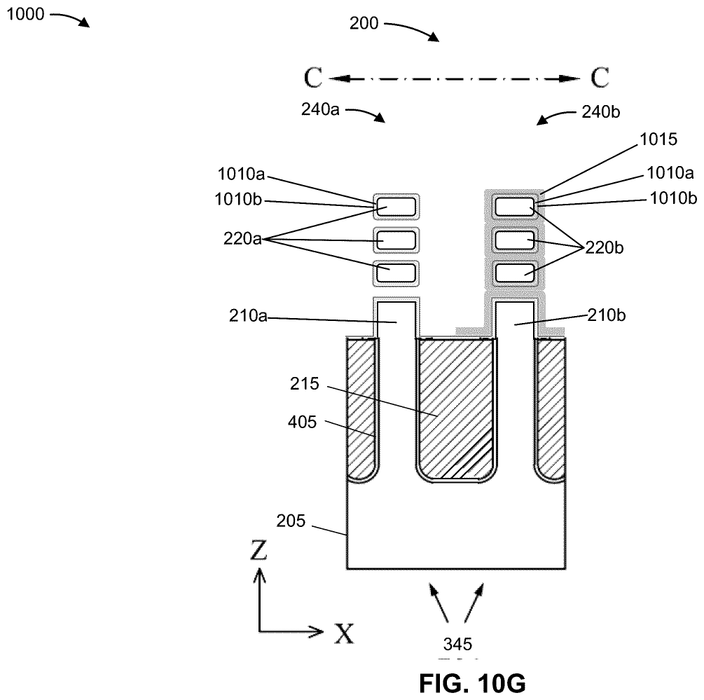

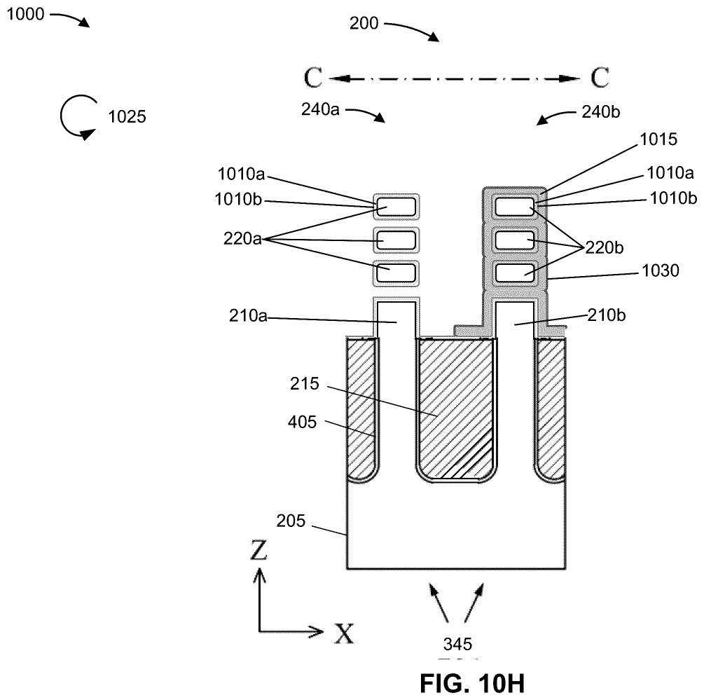

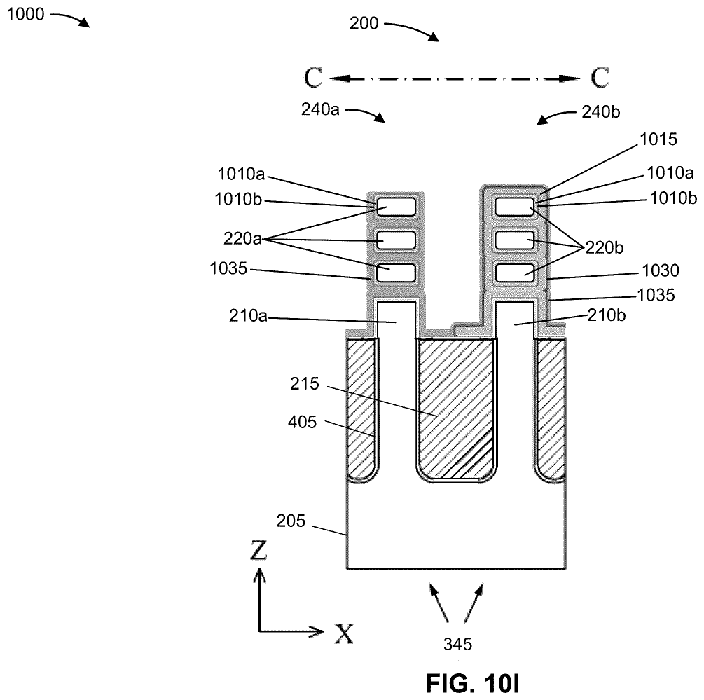

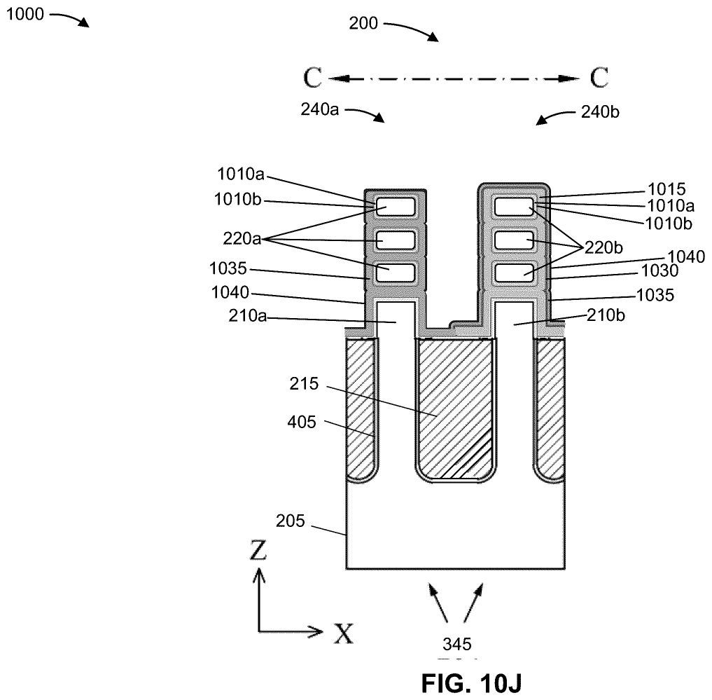

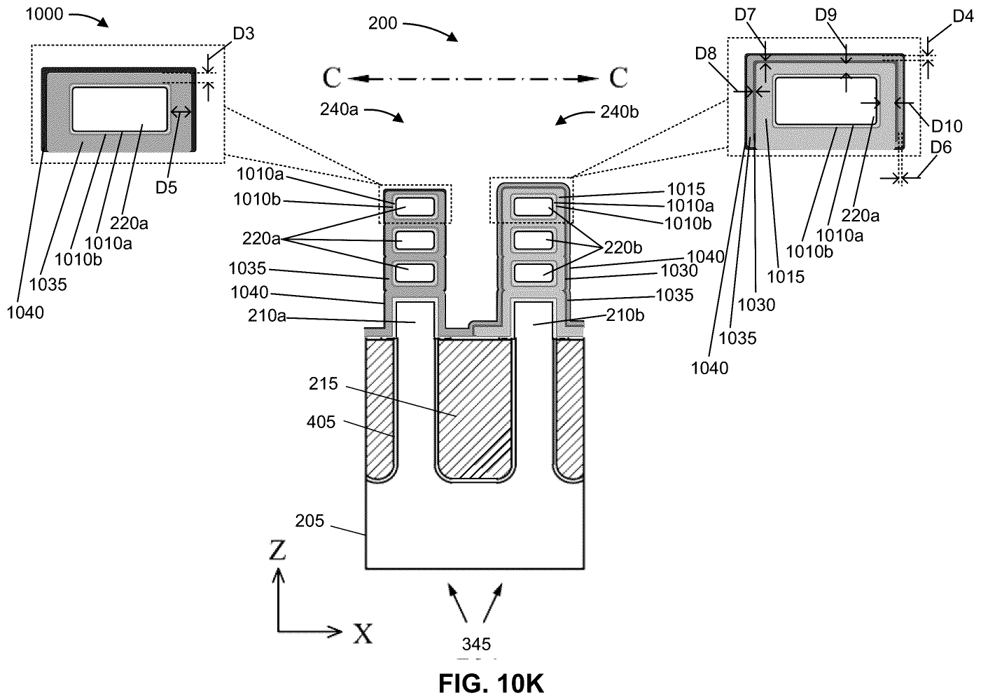

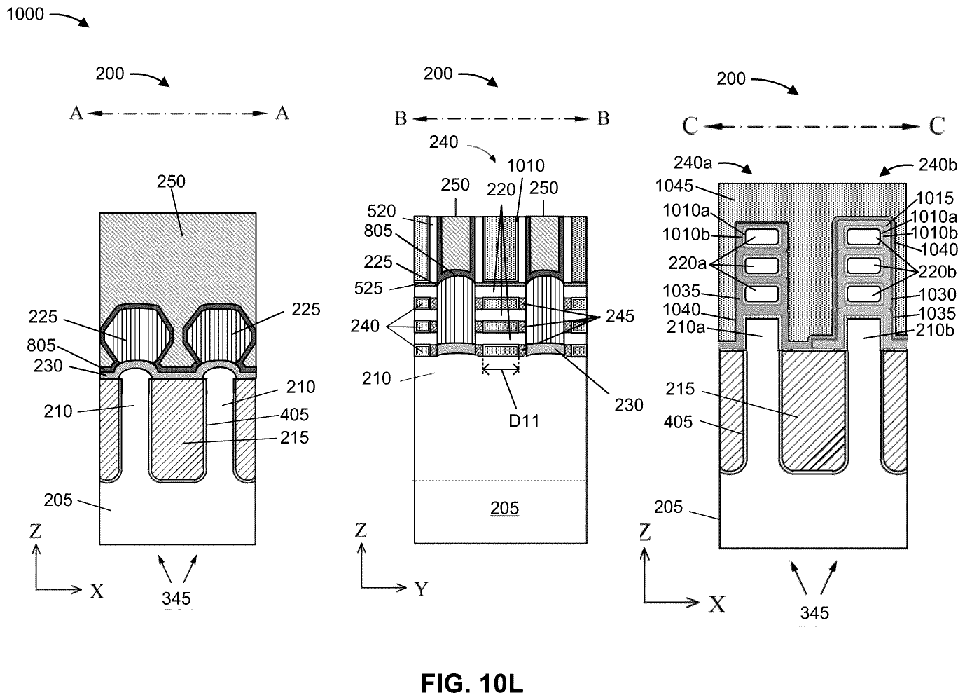

FIGS. 10A-10L are diagrams of an example implementation 1000 of a replacement gate (RPG) process described herein. The example implementation 1000 includes an example of a replacement gate process for replacing the dummy gate structures 505 with the gate structures 240 (e.g., the replacement gate structures) of the semiconductor device 200. FIGS. 10A-10L are illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 1000 are performed after the operations described in connection with FIGS. 3A-9.

As shown in the cross-sectional plane B-B and the cross-sectional plane C-C in FIG. 10A, the replacement gate operation is performed (e.g., by one or more of the semiconductor processing tools 102-112) to remove the dummy gate structures 505 from the semiconductor device 200. The removal of the dummy gate structures 505 leaves behind openings (or recesses) 1005 between the ILD layer 250 over the source/drain regions 225. The dummy gate structures 505 may be removed in one or more etch operations. Such etch operations may include a plasma etch technique, a wet chemical etch technique, and/or another type of etch technique.

The removal of the dummy gate structures 505 exposes a mesa region 210a and a stack of nanostructure channels 220a, above the mesa region 210a, that are arranged in the z-direction in the semiconductor device 200. The removal of the dummy gate structures 505 also exposes a mesa region 210b and a stack of nanostructure channels 220b, above the mesa region 210b, that are arranged in the z-direction in the semiconductor device 200. The mesa region 210a and the nanostructure channels 220a may be exposed in preparation for forming an n-type gate structure, of an NMOS nanostructure transistor of the semiconductor device 200, around the nanostructure channels 220a. The mesa region 210b and the nanostructure channels 220b may be exposed in preparation for forming an n-type gate structure, of a PMOS nanostructure transistor of the semiconductor device 200, around the nanostructure channels 220b.

As shown in the cross-sectional plane B-B and the cross-sectional plane C-C in FIG. 10B, a nanostructure release operation (e.g., an SiGe release operation) is performed to remove the first layers 310 (e.g., the silicon germanium layers). This results in openings 1005 between the nanostructures channels 220 (e.g., the areas around the nanostructure channels 220), including between the nanostructure channels 220a and between the nanostructure channels 220b. The nanostructure release operation may include the etch tool 108 performing an etch operation to remove the first layer 310 based on a difference in etch selectivity between the material of the first layers 310 and the material of the nanostructure channels 220, and between the material of the first layers 310 and the material of the inner spacers 245. The inner spacers 245 may function as etch stop layers in the etch operation to protect the source/drain regions 225 from being etched.

As further shown in FIG. 10B, the nanostructure channels 220a (e.g., the NMOS nanostructure channels) may have an x-direction width indicated in FIG. 10B as dimension D1, and the nanostructure channels 220b (e.g., the PMOS nanostructure channels) may have an x-direction width indicated in FIG. 10B as dimension D2. In some implementations, the dimension D1 and the dimension D2 are approximately the same width. In some implementations, the dimension D1 and the dimension D2 are different widths. For example, the dimension D2 may be greater than the dimension D1, or the dimension D1 may be greater than the dimension D2. In some implementations, the dimension D1 and the dimension D2 are each included in a range of approximately 8 nanometers to approximately 70 nanometers. However, other values for the range are within the scope of the present disclosure.

As shown in the cross-sectional plane C-C in FIGS. 10C-10L, the replacement gate operation continues where the gate structures (e.g., replacement gate structures) 240 are formed in the openings 1005 between the source/drain regions 225 for the nanostructure transistors of the semiconductor device 200. In particular, an n-type gate structure 240a is formed in the areas between and around the nanostructure channels 220a for an NMOS nanostructure transistor of the semiconductor device 200. The n-type gate structure 240a occupies the areas that were previously occupied by the first layers 310 such that the n-type gate structure 240a wraps around the nanostructure channels 220a and surrounds the nanostructure channels 220a on at least three sides of the nanostructure channels 220a. In some implementations, the n-type gate structure 240a fully wraps around the nanostructure channels 220a and surrounds the nanostructure channels 220a on all four sides of the nanostructure channels 220a. A p-type gate structure 240b is formed in the areas between and around the nanostructure channels 220b for a PMOS nanostructure transistor of the semiconductor device 200. The p-type gate structure 240b occupies the areas that were previously occupied by the first layers 310 such that the p-type gate structure 240b wraps around the nanostructure channels 220b and surrounds the nanostructure channels 220b on at least three sides of the nanostructure channels 220b. In some implementations, the p-type gate structure 240b fully wraps around the nanostructure channels 220b and surrounds the nanostructure channels 220b on all four sides of the nanostructure channels 220b.

As shown in FIG. 10C, one or more conformal liners may be deposited onto the exposed portion of the mesa region 210a, the exposed portion of the mesa region 210b, the nanostructure channels 220a, and the nanostructure channels 220b. The one or more conformal liners may include a high-k dielectric liner 1010a, an adhesion liner 1010b, and/or another type of liner. The high-k dielectric liner 1010a may function as a gate dielectric layer between the n-type gate structure 240a and the nanostructure channels 220a, and between the p-type gate structure 240b and the nanostructure channels 220b. The adhesion liner 1010b may promote adhesion between the high-k dielectric liner 1010a and one or more metal layers of the n-type gate structure 240a and the p-type gate structure 240b. A deposition tool 102 may be used to deposit the high-k dielectric liner 1010a and the adhesion liner 1010b, each using a PVD technique, an ALD technique, a CVD technique, an oxidation technique, another type of deposition technique described in connection with FIG. 1, and/or another suitable deposition technique. The high-k dielectric liner 1010a and the adhesion liner 1010b may each be deposited in one or more deposition operations.

The high-k dielectric liner 1010a may include one or more high-k materials (e.g., dielectric materials having a dielectric constant greater than silicon dioxide (SiO₂-dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric liner. In some implementations, the high-k dielectric liner 1010a may have a thickness that is included in a range of approximately 0.5 nanometers to approximately 3 nanometers. However, other values for the range are within the scope of the present disclosure. The adhesion liner 1010b may include tantalum nitride (TaN), titanium nitride (TiN), and/or another suitable adhesion liner material.

As further shown in FIG. 10C, a p-type metal layer 1015 is formed on the high-k dielectric liner 1010a and/or on the adhesion liner 1010b. The p-type metal layer 1015 is formed on the exposed portions of the mesa regions 210a and 210b, and on the nanostructure channels 220a and 220b such that the p-type metal layer 1015 wraps around the nanostructure channels 220a and 220b. In some embodiments, the p-type metal layer 1015 wrapping around the nanostructure channels 220a and 220b is merged between the nanostructure channels 220a and 220b. In some embodiments, the p-type metal layer 1015 wrapping around the nanostructure channels 220a and 220b is not merged between the nanostructure channels 220a and 220b. The p-type gate structure 240b includes a metal gate structure. Unlike polysilicon gate structures, for which a work function may be tuned by doping the polysilicon material with p-type dopants and/or n-type dopants, work function tuning for metal gate structures may be performed by including one or more work function tuning metals in the metal gate structures. The p-type metal layer 1015 may be included in the p-type gate structure 240b to tune the work function of the p-type gate structure 240b. The p-type metal layer 1015 may include one or more p-type metals, such as, tungsten (W), cobalt (Co), titanium nitride (TiN), tungsten nitride (WN), and/or another metal having a work function that is greater than approximately 4.7 eV, among other examples. The p-type metal layer 1015 may be included to tune the work function of the PMOS nanostructure transistor such that the work function is adjusted close to the valance band of the material of the nanostructure channels 220b. This enables a relatively low threshold voltage to be achieved for the PMOS nanostructure transistor while enabling a relatively low current leakage to be achieved for the PMOS nanostructure transistor.

A deposition tool 102 may be used to deposit the p-type metal layer 1015 using a PVD technique, an ALD technique, a CVD technique, an oxidation technique, another type of deposition technique described in connection with FIG. 1, and/or another suitable deposition technique. The p-type metal layer 1015 may be deposited in one or more deposition operations. In some implementations, the p-type metal layer 1015 is formed to a thickness that is included in a range of approximately 0.5 nanometers to approximately 20 nanometers. However, other values for the range are within the scope of the present disclosure.

As indicated above, the p-type metal layer 1015 is formed around the nanostructure channels 220a and 220b. This is due to the p-type metal layer 1015 being formed without the use of a masking layer around the nanostructure channels 220a. If the p-type metal layer 1015 were to remain around the nanostructure channels 220a, the p-type metal layer 1015 might otherwise result in the work function for the n-type gate structure 240a being too far away from the conduction band of the material of the nanostructure channels 220a. Accordingly, and as shown in FIGS. 10D-10F, the p-type metal layer 1015 is removed from the nanostructure channels 220a after formation of the p-type metal layer 1015.

As shown in FIG. 10D, a photoresist layer 1020 may be formed over the semiconductor device 200. The photoresist layer 1020 may be formed on the p-type metal layer 1015 that is on the mesa region 210a, the mesa region 210b, the nanostructure channels 220a, and the nanostructure channels 220b. A deposition tool 102 may be used to deposit the photoresist layer 1020 using a spin coating technique and/or another deposition technique.

As shown in FIG. 10E, a pattern is formed in the photoresist layer 1020. The n-type gate structure 240a, is exposed through the pattern in the photoresist layer 1020. This enables the photoresist layer 1020 to be used to remove the p-type metal layer 1015 from the mesa region 210a and the nanostructure channels 220a without removing the p-type metal layer 1015 from the mesa region 210b and the nanostructure channels 220b. An exposure tool 104 may be used to expose the photoresist layer 1020 to a radiation source to pattern the photoresist layer 1020. A developer tool 106 may be used to develop and remove portions of the photoresist layer 1020 that are on the mesa region 210a and the nanostructure channels 220a.

As shown in FIG. 10F, the portions of the p-type metal layer 1015 exposed through the pattern in the photoresist layer 1020 are removed from the mesa region 210a and from the nanostructure channels 220a. The photoresist layer 1020 over the p-type gate structure 240b protects the portions of the p-type metal layer 1015 from being removed from the mesa region 210b and from the nanostructure channels 220b. An etch tool 108 may be used to etch the p-type metal layer 1015 based on the pattern in the photoresist layer 1020 to remove the portions of the p-type metal layer 1015 from the mesa region 210a and from the nanostructure channels 220a. In some implementations, the etch operation includes a plasma etch operation, a wet chemical etch operation, and/or another type of etch operation. In some implementations, a hard mask layer is used as an alternative technique for removing the portions of the p-type metal layer 1015 from the mesa region 210a and from the nanostructure channels 220a based on a pattern.

As shown in FIG. 10G, a photoresist removal tool may be used to remove the remaining portions of the photoresist layer 1020. The remaining portions of the photoresist layer 1020 may be removed using a chemical stripper, plasma ashing, and/or another technique. Removal of the remaining portions of the photoresist layer 1020 exposes the p-type metal layer 1015 that is on the mesa region 210b and on the nanostructure channels 220b.

As shown in FIG. 10H, an oxidation operation 1025 is performed on the semiconductor device 200. The oxidation operation 1025 is performed to oxidize a surface of the p-type metal layer 1015, which results in formation of a metal oxide layer 1030 on the surface of the p-type metal layer 1015. Since the metal oxide layer 1030 is formed by oxidizing the surface of the p-type metal layer 1015, the metal oxide layer 1030 includes a material (e.g., a metal oxide material) that includes an oxide of a p-type metal of the p-type metal layer 1015. For example, if the p-type metal layer 1015 includes titanium nitride (TiN), the metal oxide layer 1030 may include a titanium oxide (TiOₓ). As another example, if the p-type metal layer 1015 includes tungsten (W), the metal oxide layer 1030 may include a tungsten oxide (WOₓ). As another example, if the p-type metal layer 1015 includes cobalt (Co), the metal oxide layer 1030 may include a cobalt oxide (CoOₓ). In some embodiments, the metal oxide layer 1030 is formed between the nanostructure channels 220b.

Performing the oxidation operation 1025 enables the metal oxide layer 1030 to be formed on the p-type gate structure 240b without forming the metal oxide layer 1030 on the nanostructure channels 220a. In this way, additional semiconductor processing steps, such as masking the nanostructure channels 220a with a masking layer and/or performing a subsequent etch to remove the metal oxide layer 1030 from the nanostructure channels 220a, can be omitted by selectively forming the metal oxide layer 1030 on the p-type gate structure 240b by performing the oxidation operation 1025. This reduces the cost, time, and manufacturing complexity of forming the semiconductor device 200, as well as reduces the likelihood of damaging the high-k dielectric liners 1010a and/or the nanostructure channels 220a.

Various oxidation techniques may be used for performing the oxidation operation 1025. In some implementations, a deposition tool 102 and/or another type of semiconductor processing tool is used to perform an oxide treatment operation on the surface of the p-type metal layer 1015 using a solution that includes ozone (O₃) dissolved in deionized water. The p-type metal layer 1015 may be submerged in the solution for a time period to enable the oxygen in the solution to oxidize the surface of the p-type metal layer 1015. The ozone concentration in the solution may be included in a range of approximately 0.1 parts per million (ppm) of the solution to approximately 107 ppm of the solution. However, other values for the range are within the scope of the present disclosure. The ozone concentration and/or the time duration may be selected to achieve a particular amount of oxidation of the surface of the p-type metal layer 1015. For example, a greater ozone concentration in the solution and/or a greater time duration may result in a greater amount of oxidation of the surface of the p-type metal layer 1015, whereas a lesser ozone concentration in the solution and/or a lesser time duration may result in a lesser amount of oxidation of the surface of the p-type metal layer 1015.

In some implementations, an oxygen-containing gas is used to perform the oxidation operation 1025. For example, a deposition tool 102 and/or another type of semiconductor processing tool may be used to expose the p-type metal layer 1015 to a gas containing ozone (O₃), nitrous oxide (N₂O), and/or another type of oxygen-containing gas for a time duration to oxidize the surface of the p-type metal layer 1015.

In some implementations, a plasma treatment operation is performed for the oxidation operation 1025. A deposition tool 102 (e.g., a plasma-based deposition tool), and etch tool 108 (e.g., a plasma-based etch tool), and/or another type of plasma-based semiconductor processing tool may be used to perform the plasma treatment operation using an oxygen (O₂) plasma and/or an oxygen-containing plasma. The oxygen ions in the oxygen plasma may bombard the surface of the p-type metal layer 1015, resulting in oxidation of the surface of the p-type metal layer 1015.

In some implementations, a thermal oxidation technique is used to perform the oxidation operation 1025. The thermal oxidation technique may include a baking operation in which the p-type metal layer 1015 is exposed to elevated temperatures for a time duration to promote oxidation of the surface of the p-type metal layer 1015. The p-type metal layer 1015 may be exposed to atmospheric gasses that contain oxygen during the baking operation such that the oxygen in the atmospheric gasses, in combination with the elevated temperatures, results in the oxidation of the surface of the p-type metal layer 1015.

The p-type metal layer 1015 may be exposed to heat during the baking operation. The temperature of the baking operation may be included in a range of approximately 230 degrees Celsius to approximately 300 degrees Celsius. If the temperature of the baking operation is less than approximately 230 degrees Celsius, the metal oxide layer 1030 may not sufficiently inhibit growth of an n-type metal layer on the p-type gate structure 240b because the metal oxide layer 1030 may not be formed to a sufficient thickness. This may result in the n-type metal layer on the p-type gate structure 240b causing the work function of the p-type gate structure 240b to be too far away from the valence band of the material of the nanostructure channels 220b, which may result in too high of a p-type threshold voltage (PVₜ) for the PMOS nanostructure transistor. If the temperature of the baking operation is greater than approximately 300 degrees Celsius, this may result in temperature instability (e.g., may result in increased negative-bias temperature instability (NTBI)) of the NMOS nanostructure transistor and/or the PMOS nanostructure transistor. This may result in increased threshold voltages for the NMOS nanostructure transistor and/or the PMOS nanostructure transistor. If the temperature of the baking operation is included in the range of approximately 230 degrees Celsius to approximately 300 degrees Celsius, the threshold voltages for the NMOS nanostructure transistor and/or for the PMOS nanostructure transistor may enable a low leakage current to be achieved for the NMOS nanostructure transistor and/or for the PMOS nanostructure transistor structure while enabling a high operating efficiency to be achieved for the NMOS nanostructure transistor and/or for the PMOS nanostructure transistor. However, other values for the temperature of the baking operation, and ranges other than approximately 230 degrees Celsius to approximately 300 degrees Celsius, are within the scope of the present disclosure.

In some implementations, a plurality of the oxidation techniques described above, and/or another oxidation technique, are used in the oxidation operation 1025 to oxidize the surface of the p-type metal layer 1015. For example, the thermal oxidation technique and the plasma treatment technique may be used in the oxidation operation 1025 to oxidize the surface of the p-type metal layer 1015.

In some implementations, the time duration of the oxidation operation 1025 may be included in a range of approximately 60 seconds to approximately 180 seconds. If the time duration is less than approximately 60 seconds, the metal oxide layer 1030 may not sufficiently inhibit growth of an n-type metal layer on the p-type gate structure 240b because the metal oxide layer 1030 may not be formed to a sufficient thickness. This may result in the n-type metal layer on the p-type gate structure 240b causing the work function of the p-type gate structure 240b to be too far away from the valence band of the material of the nanostructure channels 220b, which may result in too high of a p-type threshold voltage (PVₜ) for the PMOS nanostructure transistor. If the time duration is greater than approximately 180 seconds, silicon oxide (SiOₓ) regrowth may occur in other regions of the semiconductor device 200, which may result in degraded performance for other devices in the semiconductor device 200. Performing the oxidation operation 1025 for a time duration that is included in the range of approximately 60 seconds to approximately 180 seconds may minimize silicon oxide (SiOₓ) regrowth while enabling the metal oxide layer 1030 to be formed to a sufficient thickness to inhibit growth of an n-type metal layer on the p-type gate structure 240b. However, other values for the time duration, and ranges other than approximately 60 seconds to approximately 180 seconds, are within the scope of the present disclosure.

As shown in FIG. 10I, an n-type metal layer 1035 is formed on the n-type gate structure 240a after the oxidation operation 1025 is performed to form the metal oxide layer 1030 on the p-type gate structure 240b. The n-type metal layer 1035 is formed such that the n-type metal layer 1035 wraps around each of the nanostructure channels 220a. The n-type metal layer 1035 is also formed on the exposed portion of the mesa region 210a below the nanostructure channels 220a. A deposition tool 102 and/or a plating tool 112 may be used to deposit the n-type metal layer 1035 using a CVD technique, a PVD technique, an ALD technique, an electroplating technique, another deposition technique described above in connection with FIG. 1, and/or another suitable deposition technique. The n-type metal layer 1035 may be deposited in one or more deposition operations. In some implementations, a seed layer is first deposited, and the n-type metal layer 1035 is deposited on the seed layer.

The n-type metal layer 1035 includes one or more metal materials that tune or adjust the work function of the n-type gate structure 240a near the conduction band of the material of the nanostructure channels 220a. In some implementations, the n-type metal layer 1035 includes titanium aluminum (TiAl). In some implementations, the n-type metal layer 1035 includes titanium aluminum carbon (TiAlC). In some implementations, the n-type metal layer 1035 includes another aluminum-containing metal. In some implementations, another n-type metal material is included in the n-type metal layer 1035.

The n-type metal layer 1035 is also formed on the p-type gate structure 240b since no masking layer covers the p-type gate structure 240b during formation of the n-type metal layer 1035. However, the metal oxide layer 1030, that was formed in the oxidation operation 1025, inhibits growth of the n-type metal layer 1035 on the p-type gate structure 240b. Thus, the thickness of the n-type metal layer 1035 on the p-type gate structure 240b is less than the thickness of the n-type metal layer 1035 on the n-type gate structure 240a. In some implementations, the metal oxide layer 1030 may inhibit the growth of the n-type metal layer 1035 in that the bonding energy for bonding the atoms of the n-type metal layer 1035 with the metal oxide layer 1030 may be higher than the bonding energy for bonding the atoms of the n-type metal layer 1035 with the p-type metal layer 1015. The lesser thickness of the n-type metal layer 1035 on the p-type gate structure 240b results in the n-type metal layer 1035 on the p-type gate structure 240b having less impact on the work function of the p-type gate structure 240b than the n-type metal layer 1035 has on the work function of the n-type gate structure 240a. In particular, the lesser thickness of the n-type metal layer 1035 on the p-type gate structure 240b results in the work function of the p-type gate structure 240b being closer to the valence band of the material of the nanostructure channels 220b than if no metal oxide layer 1030 were formed on the p-type gate structure 240b. Accordingly, the metal oxide layer 1030 enables the work function of the p-type gate structure 240b to be tuned to achieve a p-type threshold voltage (PVₜ) for the PMOS nanostructure transistor that enables the PMOS nanostructure transistor to operate efficiently and with a low current leakage.

As shown in FIG. 10J, a capping layer 1040 may be formed on the n-type gate structure 240a and/or on the p-type gate structure 240b. In some implementations, the capping layer 1040 is omitted from the n-type gate structure 240a and/or the p-type gate structure 240b. The capping layer 1040 may include titanium nitride (TiN) and/or another suitable capping material. The capping layer 1040 may be formed on the n-type metal layer 1035 that is on the n-type gate structure 240a, and/or may be formed on the n-type metal layer 1035 that is on the p-type gate structure 240b. A deposition tool 102 and/or a plating tool 112 may be used to deposit the capping layer 1040 using a CVD technique, a PVD technique, an ALD technique, an electroplating technique, another deposition technique described above in connection with FIG. 1, and/or another suitable deposition technique. The capping layer 1040 may be deposited in one or more deposition operations. In some implementations, a seed layer is first deposited, and the capping layer 1040 is deposited on the seed layer.

As shown in FIG. 10K, the semiconductor device 200 may include one or more dimensions. An example dimension D3 includes a thickness of the n-type metal layer 1035 of the n-type gate structure 240a. In particular, the dimension D3 corresponds to the thickness of the n-type metal layer 1035 on a top surface of the n-type gate structure 240a. In some implementations, the dimension D3 is included in a range of approximately 0.5 nanometers to approximately 20 nanometers. If the dimension D3 is less than approximately 0.5 nanometers, the work function of the n-type gate structure 240a may be too far away from the conduction band of the material of the nanostructure channels 220a, which may result in too high of an n-type threshold voltage (NVₜ). If the dimension D3 is greater than approximately 20 nanometers, the work function of the n-type gate structure 240a may be too close to the conduction band of the material of the nanostructure channels 220a, which may result in too low of an n-type threshold voltage (NVₜ). If the dimension D3 is included in a range of approximately 0.5 nanometers to approximately 20 nanometers, the work function of the n-type gate structure 240a may enable a low leakage current to be achieved for the NMOS nanostructure transistor while enabling a high operating efficiency to be achieved for the NMOS nanostructure transistor. However, other values for the dimension D3, and ranges other than approximately 0.5 nanometers to approximately 20 nanometers, are within the scope of the present disclosure.

Another example dimension D4 includes a thickness of the n-type metal layer 1035 on the p-type gate structure 240b. In particular, the dimension D4 corresponds to the thickness of the n-type metal layer 1035 on a top surface of the p-type gate structure 240b. In some implementations, the dimension D4 is included in a range of approximately 0.1 nanometers to approximately 16 nanometers. If the dimension D4 is greater than approximately 16 nanometers, the work function of the p-type gate structure 240b may be too far away from the valance band of the material of the nanostructure channels 220b, which may result in too high of a p-type threshold voltage (PVₜ). If the dimension D4 is approximately 16 nanometers or less, the work function of the p-type gate structure 240b may enable a low leakage current to be achieved for the PMOS nanostructure transistor while enabling a high operating efficiency to be achieved for the PMOS nanostructure transistor. However, other values for the dimension D4, and ranges other than approximately 0.1 nanometers to approximately 16 nanometers, are within the scope of the present disclosure.

In some implementations, a ratio of the dimension D3 to the dimension D4 (e.g., D3:D4) is greater than approximately 1.2:1. If the ratio is less than approximately 1.2:1, the work function of the p-type gate structure 240b may be too far away from the valance band of the material of the nanostructure channels 220b, which may result in too high of a p-type threshold voltage (PVₜ), whereas the work function of the p-type gate structure 240b may enable a low leakage current to be achieved for the PMOS nanostructure transistor while enabling a high operating efficiency to be achieved for the PMOS nanostructure transistor if the ratio is greater than approximately 1.2:1. However, other values for the difference between the dimension D3 and the dimension D4 are within the scope of the present disclosure.

Another example dimension D5 includes a thickness of the n-type metal layer 1035 of the n-type gate structure 240a. In particular, the dimension D5 corresponds to the thickness of the n-type metal layer 1035 on a sidewall of the n-type gate structure 240a. In some implementations, the dimension D5 is included in a range of approximately 0.5 nanometers to approximately 20 nanometers. If the dimension D5 is less than approximately 0.5 nanometers, the work function of the n-type gate structure 240a may be too far away from the conduction band of the material of the nanostructure channels 220a, which may result in too high of an n-type threshold voltage (NVₜ). If the dimension D5 is greater than approximately 20 nanometers, the work function of the n-type gate structure 240a may be too close to the conduction band of the material of the nanostructure channels 220a, which may result in too low of an n-type threshold voltage (NVₜ). If the dimension D5 is included in a range of approximately 0.5 nanometers to approximately 20 nanometers, the work function of the n-type gate structure 240a may enable a low leakage current to be achieved for the NMOS nanostructure transistor while enabling a high operating efficiency to be achieved for the NMOS nanostructure transistor. However, other values for the dimension D5, and ranges other than approximately 0.5 nanometers to approximately 20 nanometers, are within the scope of the present disclosure. In some embodiments, the n-type metal layer 1035 is conformally deposited such that the dimension D3 is substantially equal to the dimension D5.

Another example dimension D6 includes a thickness of the n-type metal layer 1035 on the p-type gate structure 240b. In particular, the dimension D6 corresponds to the thickness of the n-type metal layer 1035 on a top surface of the p-type gate structure 240b. In some implementations, the dimension D6 is included in a range of approximately 0.1 nanometers to approximately 16 nanometers. If the dimension D6 is greater than approximately 16 nanometers, the work function of the p-type gate structure 240b may be too far away from the valance band of the material of the nanostructure channels 220b, which may result in too high of a p-type threshold voltage (PVₜ). If the dimension D6 is approximately 16 nanometers or less, the work function of the p-type gate structure 240b may enable a low leakage current to be achieved for the PMOS nanostructure transistor while enabling a high operating efficiency to be achieved for the PMOS nanostructure transistor. However, other values for the dimension D6, and ranges other than approximately 0.1 nanometers to approximately 16 nanometers, are within the scope of the present disclosure. In some embodiments, the n-type metal layer 1035 is conformally deposited such that the dimension D6 is substantially equal to the dimension D4.

In some implementations, a ratio of the dimension D5 and the dimension D6 (e.g., D5:D6) is greater than approximately 1.2:1. If the ratio is less than approximately 1.2:1, the work function of the p-type gate structure 240b may be too far away from the valance band of the material of the nanostructure channels 220b, which may result in too high of a p-type threshold voltage (PVₜ), whereas the work function of the p-type gate structure 240b may enable a low leakage current to be achieved for the PMOS nanostructure transistor while enabling a high operating efficiency to be achieved for the PMOS nanostructure transistor if the ratio is greater than approximately 1.2:1. However, other values for the difference between the dimension D5 and the dimension D6 are within the scope of the present disclosure.

In some implementations, a ratio of the dimension D3 and the dimension D5 (e.g., D3:D5) is included in a range of approximately 0.1:1 to approximately 0.5:1. However, other values for the difference between the dimension D3 and the dimension D5 are within the scope of the present disclosure. In some implementations, a ratio of the dimension D4 and the dimension D6 (e.g., D4:D6) is included in a range of approximately 0.1:1 to approximately 0.8:1. However, other values for the difference between the dimension D4 and the dimension D6 are within the scope of the present disclosure.

Another example dimension D7 includes a thickness of the metal oxide layer 1030 on the p-type metal layer 1015 of the p-type gate structure 240b. In particular, the dimension D7 corresponds to the thickness of the metal oxide layer 1030 on a top surface of the p-type gate structure 240b. In some implementations, the dimension D7 is included in a range of approximately 0.9 nanometers to approximately 1.4 nanometers. If the dimension D7 is less than approximately 0.9 nanometers, the metal oxide layer 1030 may not sufficiently inhibit growth of the n-type metal layer 1035 on the p-type gate structure 240b. This may result in the n-type metal layer 1035 on the p-type gate structure 240b causing the work function of the p-type gate structure 240b to be too far away from the valence band of the material of the nanostructure channels 220b, which may result in too high of a p-type threshold voltage (PVₜ) for the PMOS nanostructure transistor. If the dimension D7 is greater than approximately 1.4 nanometers, the gate resistance of the p-type gate structure 240b may be increased, resulting in a high of a p-type threshold voltage (PVₜ) for the PMOS nanostructure transistor. If the dimension D7 is included in a range of approximately 0.9 nanometers to approximately 1.4 nanometers, the work function of the p-type gate structure 240b may enable a low leakage current to be achieved for the PMOS nanostructure transistor while enabling a high operating efficiency to be achieved for the PMOS nanostructure transistor. However, other values for the dimension D7, and ranges other than approximately 0.9 nanometers to approximately 1.4 nanometers, are within the scope of the present disclosure.

Another example dimension D8 includes a thickness of the metal oxide layer 1030 on the p-type metal layer 1015 of the p-type gate structure 240b. In particular, the dimension D7 corresponds to the thickness of the metal oxide layer 1030 on a sidewall of the p-type gate structure 240b. In some implementations, the dimension D8 is included in a range of approximately 0.7 nanometers to approximately 1.3 nanometers. If the dimension D8 is less than approximately 0.7 nanometers, the metal oxide layer 1030 may not sufficiently inhibit growth of the n-type metal layer 1035 on the p-type gate structure 240b. This may result in the n-type metal layer 1035 on the p-type gate structure 240b causing the work function of the p-type gate structure 240b to be too far away from the valence band of the material of the nanostructure channels 220b, which may result in too high of a p-type threshold voltage (PVₜ) for the PMOS nanostructure transistor. If the dimension D8 is greater than approximately 1.3 nanometers, the gate resistance of the p-type gate structure 240b may be increased, resulting in a high of a p-type threshold voltage (PVₜ) for the PMOS nanostructure transistor. If the dimension D8 is included in a range of approximately 0.7 nanometers to approximately 1.3 nanometers, the work function of the p-type gate structure 240b may enable a low leakage current to be achieved for the PMOS nanostructure transistor while enabling a high operating efficiency to be achieved for the PMOS nanostructure transistor. However, other values for the dimension D8, and ranges other than approximately 0.7 nanometers to approximately 1.3 nanometers, are within the scope of the present disclosure.

Another example dimension D9 includes a thickness of the p-type metal layer 1015 of the p-type gate structure 240b. In particular, the dimension D9 corresponds to the thickness of the p-type metal layer 1015 on a top surface of the p-type gate structure 240b. In some implementations, the dimension D9 is included in a range of approximately 0.5 nanometers to approximately 20 nanometers. If the dimension D9 is less than approximately 0.5 nanometers, the work function of the p-type gate structure 240b may be too far away from the valence band of the material of the nanostructure channels 220b, which may result in too high of a p-type threshold voltage (PVₜ). If the dimension D9 is greater than approximately 20 nanometers, the work function of the p-type gate structure 240b may be too close to the valence band of the material of the nanostructure channels 220b, which may result in too low of a p-type threshold voltage (PVₜ). If the dimension D9 is included in a range of approximately 0.5 nanometers to approximately 20 nanometers, the work function of the p-type gate structure 240b may enable a low leakage current to be achieved for the PMOS nanostructure transistor while enabling a high operating efficiency to be achieved for the PMOS nanostructure transistor. However, other values for the dimension D9, and ranges other than approximately 0.5 nanometers to approximately 20 nanometers, are within the scope of the present disclosure. In some embodiments, the p-type metal layer 1015 is conformally deposited such that the dimension D9 is substantially equal to the dimension D10.

Another example dimension D10 includes a thickness of the p-type metal layer 1015 of the p-type gate structure 240b. In particular, the dimension D10 corresponds to the thickness of the p-type metal layer 1015 on a sidewall of the p-type gate structure 240b. In some implementations, the dimension D10 is included in a range of approximately 0.5 nanometers to approximately 20 nanometers. If the dimension D10 is less than approximately 0.5 nanometers, the work function of the p-type gate structure 240b may be too far away from the valence band of the material of the nanostructure channels 220b, which may result in too high of a p-type threshold voltage (PVₜ). If the dimension D10 is greater than approximately 20 nanometers, the work function of the p-type gate structure 240b may be too close to the valence band of the material of the nanostructure channels 220b, which may result in too low of a p-type threshold voltage (PVₜ). If the dimension D10 is included in a range of approximately 0.5 nanometers to approximately 20 nanometers, the work function of the p-type gate structure 240b may enable a low leakage current to be achieved for the PMOS nanostructure transistor while enabling a high operating efficiency to be achieved for the PMOS nanostructure transistor. However, other values for the dimension D10, and ranges other than approximately 0.5 nanometers to approximately 20 nanometers, are within the scope of the present disclosure.

As shown in FIG. 10L, a gate electrode layer 1045 of the n-type gate structure 240a and the p-type gate structure 240b is formed over the n-type metal layer 1035 and over the p-type metal layer 1015. The gate electrode layer 1045 includes one or more metal materials, such as ruthenium (Ru), tungsten (W), cobalt (Co), copper (Cu), and/or molybdenum (Mo), among other examples. A deposition tool 102 and/or a plating tool 112 may be used to deposit the gate electrode layer 1045 using a CVD technique, a PVD technique, an ALD technique, an electroplating technique, another deposition technique described above in connection with FIG. 1, and/or another suitable deposition technique. The gate electrode layer 1045 may be deposited in one or more deposition operations. In some implementations, a seed layer is first deposited, and the gate electrode layer 1045 is deposited on the seed layer. In some implementations, a planarization tool 110 may be used to planarize the gate electrode layer 1045 after the gate electrode layer 1045 is deposited.

In this way, the semiconductor device 200 may include a plurality of nanostructure channels 220a arranged in the z-direction that is approximately perpendicular to the semiconductor substrate 205 of the semiconductor device 200, and a plurality of nanostructure channels 220b arranged in the z-direction that is approximately perpendicular to the semiconductor substrate 205 of the semiconductor device 200. The nanostructure channels 220a and 220b may be adjacent to each other in the semiconductor device 200. The semiconductor device 200 may include an n-type gate structure 240a wrapping around the nanostructure channels 220a, and a p-type gate structure 240b wrapping around the nanostructure channels 220b. The p-type gate structure 240b may include a p-type metal layer 1015 and a metal oxide layer 1030 on the p-type metal layer 1015, the metal oxide layer 1030 including a material that includes an oxide of a p-type metal of the p-type metal layer 1015. The n-type gate structure 240a may include n-type metal layer 1035, where the n-type metal layer 1035 is also included over the metal oxide layer 1030 of the p-type gate structure 240b.

As indicated above, the number and arrangement of operations and devices shown in FIGS. 10A-10L are provided as one or more examples. In practice, there may be additional operations and devices, fewer operations and devices, different operations and devices, or differently arranged operations and devices than those shown in FIGS. 10A-10L.

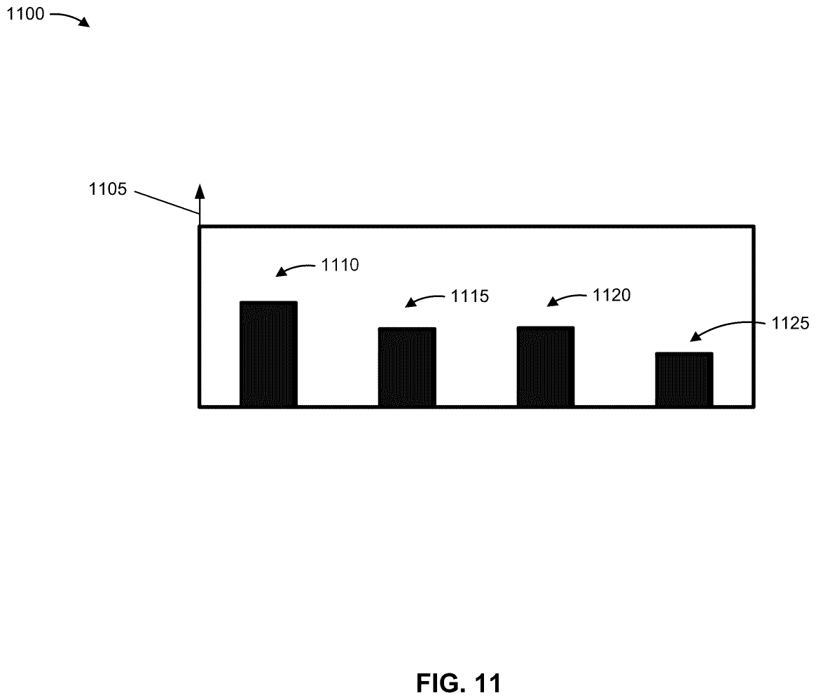

FIG. 11 is a diagram of an example 1100 of n-metal thicknesses 1105 for various types of p-metal oxidation techniques described herein. The n-metal thicknesses 1105 correspond to a thickness of an n-type metal layer on various p-type gate structures. Reference number 1110 corresponds to an n-metal thickness 1105 of an n-type metal layer on a p-type gate structure for which no metal oxide layer 1030 was formed. Reference number 1115 corresponds to an n-metal thickness 1105 of an n-type metal layer on a p-type gate structure for which a metal oxide layer 1030 was formed using a thermal oxidation technique (e.g., a baking operation) for the oxidation operation 1025 described in connection with FIG. 10H. Reference number 1120 corresponds to an n-metal thickness 1105 of an n-type metal layer on a p-type gate structure for which a metal oxide layer 1030 was formed using a thermal oxidation technique (e.g., a baking operation) for the oxidation operation 1025 described in connection with FIG. 10H. The time duration of the baking operation associated with reference number 1120 is greater than the time duration of the baking operation associated with the reference number 1115. Reference number 1125 corresponds to an n-metal thickness 1105 of an n-type metal layer on a p-type gate structure for which a metal oxide layer 1030 was formed using a plasma treatment technique (e.g., a plasma treatment using an oxygen (O₂) plasma and/or an oxygen-containing plasma) for the oxidation operation 1025 described in connection with FIG. 10H.

As shown in FIG. 11, the oxidation operation 1025 results in n-metal thicknesses 1105 (corresponding to reference numbers 1115, 1120, and 1125) that are less than the n-metal thickness 1105 without the oxidation operation 1025 (corresponding to reference number 1110). While the plasma treatment technique (corresponding to reference number 1125) may result in the lowest n-metal thickness 1105 for the n-type metal layer on the p-type gate structure, the baking operation techniques (corresponding to reference number 1115 and 1120) may also provide sufficient oxidation of the p-type metal layer on the p-type gate structure for inhibiting growth of the n-type metal layer on the p-type gate structure.

As indicated above, FIG. 11 is provided as an example. Other examples may differ from what is described with regard to FIG. 11.

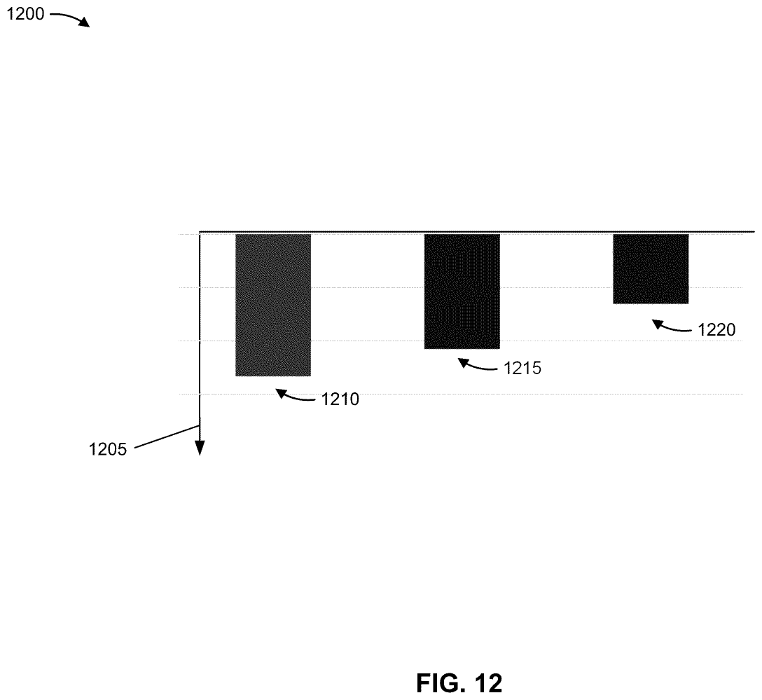

FIG. 12 is a diagram of an example 1200 of flat-band voltages (V_{fb}) 1205 of a p-type gate structure for various types of p-metal oxidation techniques described herein. As shown in FIG. 12, the flat-band voltages 1205 are illustrated for a p-type gate structure for which no metal oxide layer 1030 was formed (corresponding to reference number 1210), and for which a metal oxide layer 1030 was formed (corresponding to reference numbers 1215 and 1220) by using a thermal oxidation technique for the oxidation operation 1025 described in connection with FIG. 10H. Reference number 1215 corresponds to a flat-band voltage 1205 for a p-type gate structure for which the p-type metal layer was deposited at a greater temperature than the temperature at which the p-type metal layer was deposited for a p-type gate structure associated with the reference number 1220.

As shown in FIG. 12, the metal oxide layer 1030 enables flat-band voltages 1205 to be achieved for the p-type gate structures that are closer to zero (0) than the flat-band voltage 1205 for the p-type gate structure that was formed without the metal oxide layer 1030. The flat-band voltage 1205 corresponds to the voltage bias that may be applied to the p-type gate structure to achieve a flat-band state between the p-type gate structure and a semiconductor channel. The flat-band state refers to an energy state in which the energy bands (e.g., the conduction band and the valence band) are flat at the interface between the semiconductor channel and the gate dielectric between the semiconductor channel and the p-type gate structure. The flat-band state may enable a surface electric field of approximately zero magnitude to be achieved in the semiconductor channel. Thus, the oxidation operation 1025 for forming the metal oxide layer 1030 may enable lesser flat-band voltages 1205 to be used to achieve the flat-band state between the p-type gate structure and a semiconductor channel.

As indicated above, FIG. 12 is provided as an example. Other examples may differ from what is described with regard to FIG. 12.

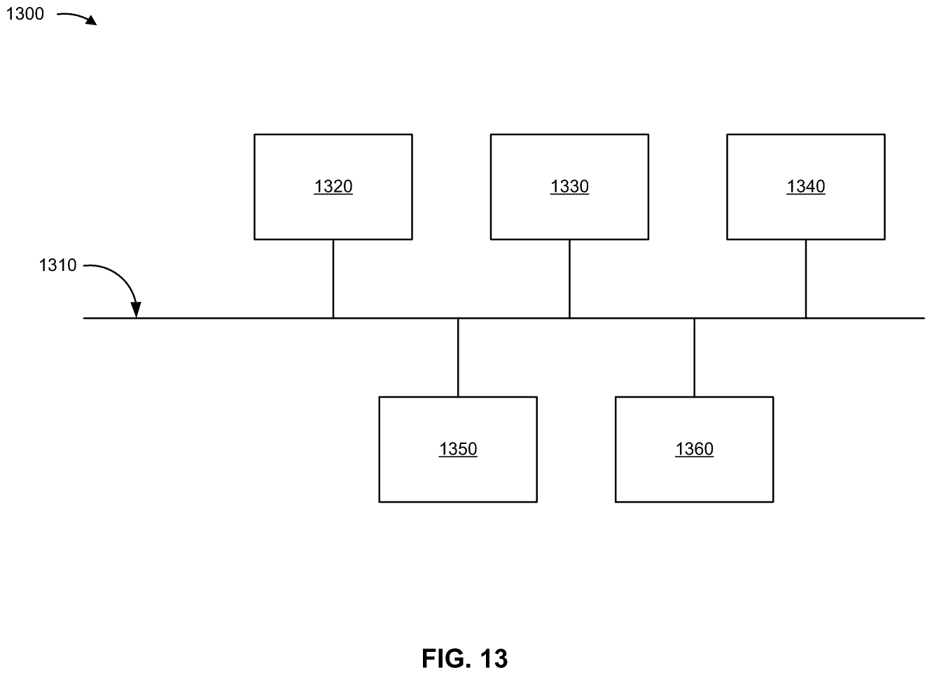

FIG. 13 is a diagram of example components of a device 1300 described herein. In some implementations, one or more of the semiconductor processing tools 102-112 and/or the wafer/die transport tool 114 may include one or more devices 1300 and/or one or more components of the device 1300. As shown in FIG. 13, the device 1300 may include a bus 1310, a processor 1320, a memory 1330, an input component 1340, an output component 1350, and/or a communication component 1360.

The bus 1310 may include one or more components that enable wired and/or wireless communication among the components of the device 1300. The bus 1310 may couple together two or more components of FIG. 13, such as via operative coupling, communicative coupling, electronic coupling, and/or electric coupling. For example, the bus 1310 may include an electrical connection (e.g., a wire, a trace, and/or a lead) and/or a wireless bus. The processor 1320 may include a central processing unit, a graphics processing unit, a microprocessor, a controller, a microcontroller, a digital signal processor, a field-programmable gate array, an application-specific integrated circuit, and/or another type of processing component. The processor 1320 may be implemented in hardware, firmware, or a combination of hardware and software. In some implementations, the processor 1320 may include one or more processors capable of being programmed to perform one or more operations or processes described elsewhere herein.

The memory 1330 may include volatile and/or nonvolatile memory. For example, the memory 1330 may include random access memory (RAM), read only memory (ROM), a hard disk drive, and/or another type of memory (e.g., a flash memory, a magnetic memory, and/or an optical memory). The memory 1330 may include internal memory (e.g., RAM, ROM, or a hard disk drive) and/or removable memory (e.g., removable via a universal serial bus connection). The memory 1330 may be a non-transitory computer-readable medium. The memory 1330 may store information, one or more instructions, and/or software (e.g., one or more software applications) related to the operation of the device 1300. In some implementations, the memory 1330 may include one or more memories that are coupled (e.g., communicatively coupled) to one or more processors (e.g., processor 1320), such as via the bus 1310. Communicative coupling between a processor 1320 and a memory 1330 may enable the processor 1320 to read and/or process information stored in the memory 1330 and/or to store information in the memory 1330.

The input component 1340 may enable the device 1300 to receive input, such as user input and/or sensed input. For example, the input component 1340 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1350 may enable the device 1300 to provide output, such as via a display, a speaker, and/or a light-emitting diode. The communication component 1360 may enable the device 1300 to communicate with other devices via a wired connection and/or a wireless connection. For example, the communication component 1360 may include a receiver, a transmitter, a transceiver, a modem, a network interface card, and/or an antenna.

The device 1300 may perform one or more operations or processes described herein. For example, a non-transitory computer-readable medium (e.g., memory 1330) may store a set of instructions (e.g., one or more instructions or code) for execution by the processor 1320. The processor 1320 may execute the set of instructions to perform one or more operations or processes described herein. In some implementations, execution of the set of instructions, by one or more processors 1320, causes the one or more processors 1320 and/or the device 1300 to perform one or more operations or processes described herein. In some implementations, hardwired circuitry may be used instead of or in combination with the instructions to perform one or more operations or processes described herein. Additionally, or alternatively, the processor 1320 may be configured to perform one or more operations or processes described herein. Thus, implementations described herein are not limited to any specific combination of hardware circuitry and software.

The number and arrangement of components shown in FIG. 13 are provided as an example. The device 1300 may include additional components, fewer components, different components, or differently arranged components than those shown in FIG. 13. Additionally, or alternatively, a set of components (e.g., one or more components) of the device 1300 may perform one or more functions described as being performed by another set of components of the device 1300.

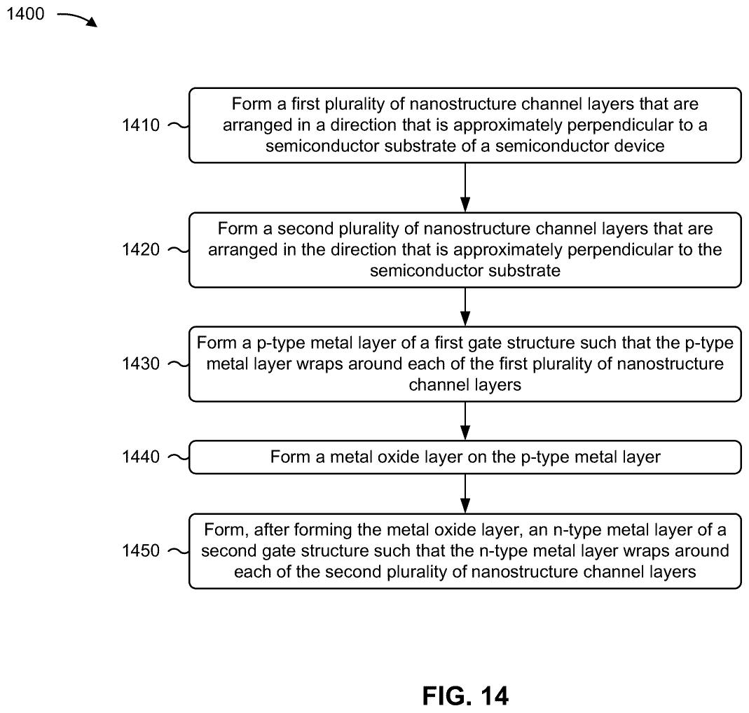

FIG. 14 is a flowchart of an example process 1400 associated with forming a semiconductor device described herein. In some implementations, one or more process blocks of FIG. 14 are performed using one or more semiconductor processing tools (e.g., one or more of the semiconductor processing tools 102-112). Additionally, or alternatively, one or more process blocks of FIG. 14 may be performed using one or more components of device 1300, such as processor 1320, memory 1330, input component 1340, output component 1350, and/or communication component 1360.

As shown in FIG. 14, process 1400 may include forming a first plurality of nanostructure channel layers that are arranged in a direction that is approximately perpendicular to a semiconductor substrate of a semiconductor device (block 1410). For example, one or more of the semiconductor processing tools 102-112 may be used to form a first plurality of nanostructure channel layers (e.g., nanostructure channels 220b) that are arranged in a direction (e.g., a z-direction) that is approximately perpendicular to a semiconductor substrate (e.g., a semiconductor substrate 205) of a semiconductor device (e.g., a semiconductor device 200), as described herein.

As further shown in FIG. 14, process 1400 may include forming a second plurality of nanostructure channel layers that are arranged in the direction that is approximately perpendicular to the semiconductor substrate (block 1420). For example, one or more of the semiconductor processing tools 102-112 may be used to form a second plurality of nanostructure channel layers (e.g., nanostructure channels 220a) that are arranged in the direction (e.g., the z-direction) that is approximately perpendicular to the semiconductor substrate (e.g., the semiconductor substrate 205), as described herein.

As further shown in FIG. 14, process 1400 may include forming a p-type metal layer of a first gate structure such that the p-type metal layer wraps around each of the first plurality of nanostructure channel layers (block 1430). For example, one or more of the semiconductor processing tools 102-112 may be used to form a p-type metal layer (e.g., a p-type metal layer 1015) of a first gate structure (e.g., a p-type gate structure 240b) such that the p-type metal layer wraps around each of the first plurality of nanostructure channel layers, as described herein.

As further shown in FIG. 14, process 1400 may include forming a metal oxide layer on the p-type metal layer (block 1440). For example, one or more of the semiconductor processing tools 102-112 may be used to form a metal oxide layer (e.g., a metal oxide layer 1030) on the p-type metal layer, as described herein.

As further shown in FIG. 14, process 1400 may include forming, after forming the metal oxide layer, an n-type metal layer of a second gate structure such that the n-type metal layer wraps around each of the second plurality of nanostructure channel layers (block 1450). For example, one or more of the semiconductor processing tools 102-112 may be used to form, after forming the metal oxide layer, an n-type metal layer (e.g., an n-type metal layer 1035) of a second gate structure (e.g., an n-type gate structure 240a) such that the n-type metal layer wraps around each of the second plurality of nanostructure channel layers, as described herein.

Process 1400 may include additional implementations, such as any single implementation or any combination of implementations described below and/or in connection with one or more other processes described elsewhere herein.

In a first implementation, forming the metal oxide layer includes oxidizing a surface of the p-type metal layer to form the metal oxide layer.

In a second implementation, alone or in combination with the first implementation, oxidizing the surface of the p-type metal layer includes performing, using a solution that includes ozone (O₃) dissolved in deionized water, an oxide treatment operation (e.g., an oxidation operation 1025) on the surface of the p-type metal layer.

In a third implementation, alone or in combination with one or more of the first and second implementations, oxidizing the surface of the p-type metal layer includes performing a baking operation (e.g., an oxidation operation 1025) to oxidize the surface of the p-type metal layer.

In a fourth implementation, alone or in combination with one or more of the first through third implementations, oxidizing the surface of the p-type metal layer includes performing a plasma treatment operation (e.g., an oxidation operation 1025) on the surface of the p-type metal layer to oxidize the surface of the p-type metal layer.

In a fifth implementation, alone or in combination with one or more of the first through fourth implementations, oxidizing the surface of the p-type metal layer includes performing, using an oxygen-containing gas, an oxide treatment operation (e.g., an oxidation operation 1025) on the surface of the p-type metal layer.

In a sixth implementation, alone or in combination with one or more of the first through fifth implementations, the p-type metal layer includes a titanium nitride (TiₓN_{y}), and the metal oxide layer includes a titanium oxide (TiOₓ).

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

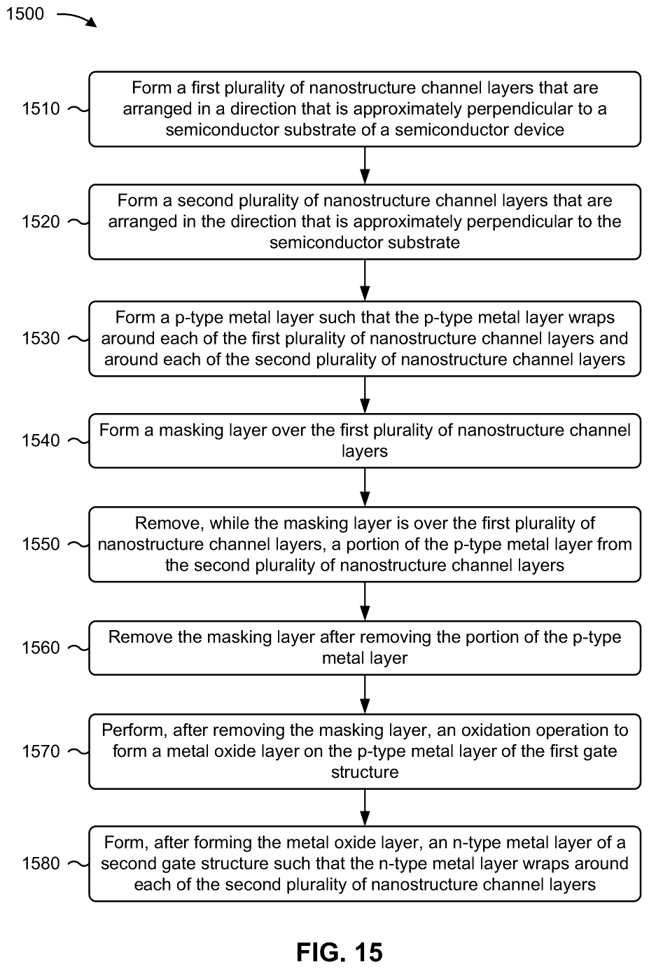

FIG. 15 is a flowchart of an example process 1500 associated with forming a semiconductor device described herein. In some implementations, one or more process blocks of FIG. 15 are performed using one or more semiconductor processing tools (e.g., one or more of the semiconductor processing tools 102-112). Additionally, or alternatively, one or more process blocks of FIG. 15 may be performed using one or more components of device 1300, such as processor 1320, memory 1330, input component 1340, output component 1350, and/or communication component 1360.

As shown in FIG. 15, process 1500 may include forming a first plurality of nanostructure channel layers that are arranged in a direction that is approximately perpendicular to a semiconductor substrate of a semiconductor device (block 1510). For example, one or more of the semiconductor processing tools 102-112 may be used to form a first plurality of nanostructure channel layers (e.g., nanostructure channels 220b) that are arranged in a direction (e.g., a z-direction) that is approximately perpendicular to a semiconductor substrate (e.g., a semiconductor substrate 205) of a semiconductor device (e.g., a semiconductor device 200), as described herein.

As further shown in FIG. 15, process 1500 may include forming a second plurality of nanostructure channel layers that are arranged in the direction that is approximately perpendicular to the semiconductor substrate (block 1520). For example, one or more of the semiconductor processing tools 102-112 may be used to form a second plurality of nanostructure channel layers (e.g., nanostructure channels 220a) that are arranged in the direction (e.g., the z-direction) that is approximately perpendicular to the semiconductor substrate (e.g., the semiconductor substrate 205), as described herein.

As further shown in FIG. 15, process 1500 may include forming a p-type metal layer such that the p-type metal layer wraps around each of the first plurality of nanostructure channel layers and around each of the second plurality of nanostructure channel layers (block 1530). For example, one or more of the semiconductor processing tools 102-112 may be used to form a p-type metal layer (e.g., a p-type metal layer 1015) such that the p-type metal layer wraps around each of the first plurality of nanostructure channel layers and around each of the second plurality of nanostructure channel layers, as described herein.

As further shown in FIG. 15, process 1500 may include forming a masking layer over the first plurality of nanostructure channel layers (block 1540). For example, one or more of the semiconductor processing tools 102-112 may be used to form a masking layer (e.g., a masking layer 1020) over the first plurality of nanostructure channel layers, as described herein.

As further shown in FIG. 15, process 1500 may include removing, while the masking layer is over the first plurality of nanostructure channel layers, a portion of the p-type metal layer from the second plurality of nanostructure channel layers (block 1550). For example, one or more of the semiconductor processing tools 102-112 may be used to remove, while the masking layer is over the first plurality of nanostructure channel layers, a portion of the p-type metal layer from the second plurality of nanostructure channel layers, as described herein. In some implementations, a remaining portion of the p-type metal layer wrapping around the first plurality of nanostructure channel layers corresponds to a first gate structure (e.g., a p-type gate structure 240b).

As further shown in FIG. 15, process 1500 may include removing the masking layer after removing the portion of the p-type metal layer (block 1560). For example, one or more of the semiconductor processing tools 102-112 may be used to remove the masking layer after removing the portion of the p-type metal layer, as described herein.

As further shown in FIG. 15, process 1500 may include performing, after removing the masking layer, an oxidation operation to form a metal oxide layer on the p-type metal layer of the first gate structure (block 1570). For example, one or more of the semiconductor processing tools 102-112 may be used to perform, after removing the masking layer, an oxidation operation (e.g., an oxidation operation 1025) to form a metal oxide layer (e.g., a metal oxide layer 1030) on the p-type metal layer of the first gate structure, as described herein.

As further shown in FIG. 15, process 1500 may include forming, after forming the metal oxide layer, an n-type metal layer of a second gate structure such that the n-type metal layer wraps around each of the second plurality of nanostructure channel layers (block 1580). For example, one or more of the semiconductor processing tools 102-112 may be used to form, after forming the metal oxide layer, an n-type metal layer (e.g., an n-type metal layer 1035) of a second gate structure (e.g., an n-type gate structure 240a) such that the n-type metal layer wraps around each of the second plurality of nanostructure channel layers, as described herein.

Process 1500 may include additional implementations, such as any single implementation or any combination of implementations described below and/or in connection with one or more other processes described elsewhere herein.

In a first implementation, performing the oxidation operation includes performing a baking operation to oxidize a surface of the p-type metal layer.

In a second implementation, alone or in combination with the first implementation, performing the baking operation includes performing the baking operation at a temperature that is included in a range of approximately 230 degrees Celsius to approximately 300 degrees Celsius.

In a third implementation, alone or in combination with one or more of the first and second implementations, a portion of the n-type metal layer is formed on the metal oxide layer, and a thickness (e.g., a dimension D4, a dimension D6) of the portion of the n-type metal layer on the metal oxide layer is less than a thickness (e.g., a dimension D3, a dimension D5) of the n-type metal layer that wraps around each of the second plurality of nanostructure channel layers.

In a fourth implementation, alone or in combination with one or more of the first through third implementations, performing the oxidation operation includes performing the oxidation operation using at least one of an ozone (O₃) gas or a nitrous oxide (N₂O) gas.

In a fifth implementation, alone or in combination with one or more of the first through fourth implementations, performing the oxidation operation comprises performing the oxidation operation using an oxygen (O₂) plasma.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

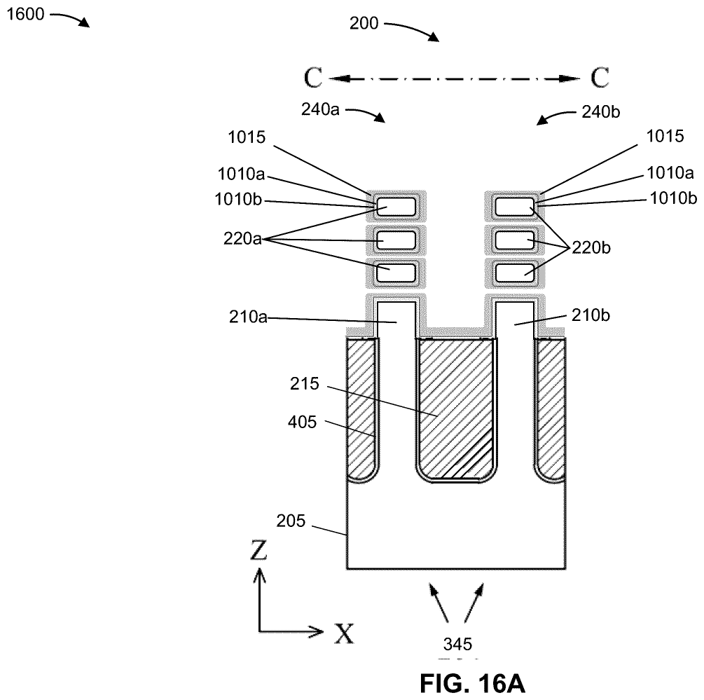

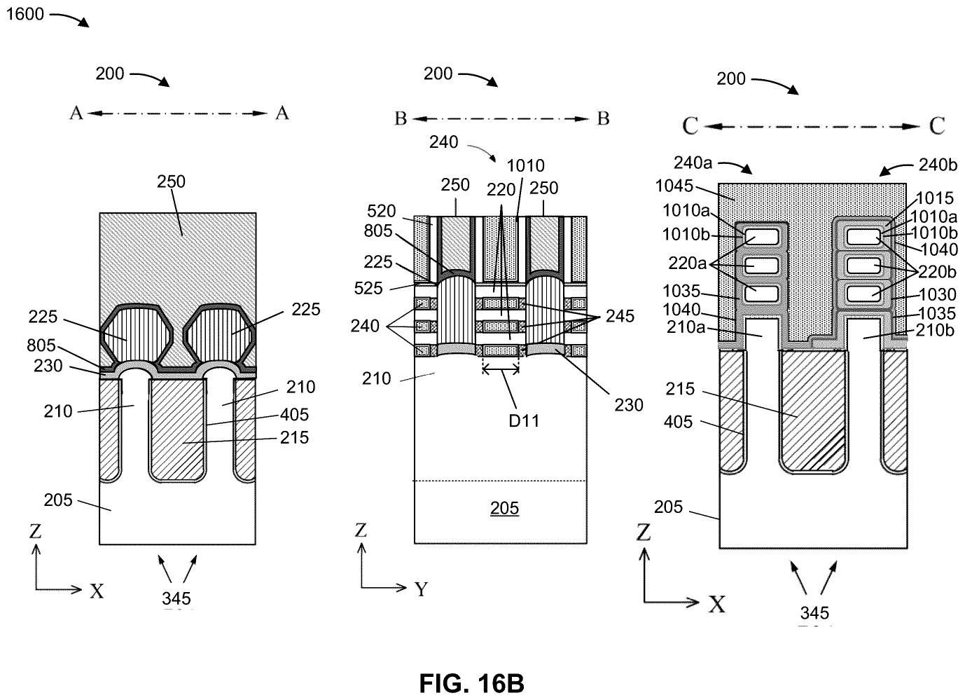

FIGS. 16A and 16B are diagrams of an example implementation 1600 of an RPG process described herein. The example implementation 1600 includes an example of a replacement gate process for replacing the dummy gate structures 505 with the gate structures 240 (e.g., the replacement gate structures) of the semiconductor device 200. FIGS. 16A and 16B are illustrated from a plurality of perspectives illustrated in FIG. 5, including the perspective of the cross-sectional plane A-A in FIG. 5, the perspective of the cross-sectional plane B-B in FIG. 5, and the perspective of the cross-sectional plane C-C in FIG. 5. In some implementations, the operations described in connection with the example implementation 1600 are performed after the operations described in connection with FIGS. 3A-9.

As shown in FIG. 16A, a high-k dielectric liner 1010a, an adhesion liner 1010b, and/or another type of liner are formed on the nanostructure channels 220a and 220b. The a high-k dielectric liner 1010a and the adhesion liner 1010b may be formed in a similar manner as described above in connection with FIG. 10C.

As further shown in FIG. 16A, a p-type metal layer 1015 is formed on the high-k dielectric liner 1010a and/or on the adhesion liner 1010b. The p-type metal layer 1015 may be formed in a similar manner as described above in connection with FIG. 10C, except that the p-type metal layer 1015 wrapping around the nanostructure channels 220a and 220b is not merged between the nanostructure channels 220a and 220b.

As shown in FIG. 16B, the operations described in connection with FIG. 10D-10L may be performed to form the n-type gate structures 240a around the nanostructure channels 220a and the p-type gate structure 240b around the nanostructure channels 220b. However, in FIG. 16B, because the p-type metal layer 1015 wrapping around the nanostructure channels 220b was not merged between the nanostructure channels 220b, the metal oxide layer 1030 of the p-type gate structure 240b is formed between the nanostructure channels 220b.

As indicated above, the number and arrangement of operations and devices shown in FIGS. 16A and 16B are provided as one or more examples. In practice, there may be additional operations and devices, fewer operations and devices, different operations and devices, or differently arranged operations and devices than those shown in FIGS. 16A and 16B.

In this way, PMOS nanostructure transistors and NMOS nanostructure transistors may be formed in a semiconductor device. The techniques described herein include forming respective (different) types of gate metals for a PMOS nanostructure transistor and keep an intrinsic NMOS nanostructure transistor of the semiconductor device. A p-type gate metal may be formed around nanostructure channels for the PMOS nanostructure transistor. The surface of the p-type gate metal may then be oxidized to form a metal oxide layer on the p-type gate metal. During formation of an n-type gate metal around the nanostructure channels for the NMOS nanostructure transistor, the metal oxide layer on the p-type gate metal resists formation of the n-type gate metal on the p-type gate metal. This results in little to no n-type gate metal deposition on the p-type gate metal, which minimizes the p-type threshold voltage (PVₜ) impact to the PMOS nanostructure transistor. In this way, the techniques described herein enable the work functions of the NMOS nanostructure transistor and the PMOS nanostructure transistor to both be tuned for achieving desirable threshold voltages for the NMOS nanostructure transistor and the PMOS nanostructure transistor. This enables low current leakages to be achieved for the NMOS nanostructure transistor and the PMOS nanostructure transistor, and enables a high operating efficiency to be achieved for the NMOS nanostructure transistor and the PMOS nanostructure transistor.

As described in greater detail herein, some implementations described herein include a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a p-type metal layer of a first gate structure such that the p-type metal layer wraps around each of the first plurality of nanostructure channel layers. The method includes forming a metal oxide layer on the p-type metal layer. The method includes forming, after forming the metal oxide layer, an n-type metal layer of a second gate structure such that the n-type metal layer wraps around each of the second plurality of nanostructure channel layers.

As described in greater detail herein, some implementations described herein include a semiconductor device. The semiconductor device includes a first plurality of nanostructure channel layers arranged in a direction that is approximately perpendicular to a semiconductor substrate of the semiconductor device. The semiconductor device includes a second plurality of nanostructure channel layers, adjacent to the first plurality of nanostructure channel layers, that are arranged in the direction that is approximately perpendicular to the semiconductor substrate. The semiconductor device includes a first gate structure, wrapping around the first plurality of nanostructure channel layers, that includes a p-type metal layer and a metal oxide layer that includes a material that includes an oxide of a p-type metal of the p-type metal layer. The semiconductor device includes a second gate structure, wrapping around each of the second plurality of nanostructure channel layers, comprising an n-type metal layer, where the n-type metal layer is included over the metal oxide layer of the first gate structure.

As described in greater detail herein, some implementations described herein include a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a p-type metal layer such that the p-type metal layer wraps around each of the first plurality of nanostructure channel layers and around each of the second plurality of nanostructure channel layers. The method includes forming a masking layer over the first plurality of nanostructure channel layers. The method includes removing, while the masking layer is over the first plurality of nanostructure channel layers, a portion of the p-type metal layer from the second plurality of nanostructure channel layers, where a remaining portion of the p-type metal layer wrapping around the first plurality of nanostructure channel layers corresponds to a first gate structure. The method includes removing the masking layer after removing the portion of the p-type metal layer. The method includes performing, after removing the masking layer, an oxidation operation to form a metal oxide layer on the p-type metal layer of the first gate structure. The method includes forming, after forming the metal oxide layer, an n-type metal layer of a second gate structure such that the n-type metal layer wraps around each of the second plurality of nanostructure channel layers.

As described in greater detail herein, some implementations described herein include a method. The method includes forming a first plurality of nanostructure channel layers that are arranged in a direction that is approximately perpendicular to a semiconductor substrate of a semiconductor device. The method includes forming a second plurality of nanostructure channel layers that are arranged in the direction that is approximately perpendicular to the semiconductor substrate. The method includes forming a first type metal layer wrapping around each of the first plurality of nanostructure channel layers. The method includes forming a metal oxide layer on the first type metal layer. The method includes forming a second type metal layer on the metal oxide layer and on the second plurality of nanostructure channel layers. A first thickness of the second type metal layer on the metal oxide layer is different from a second thickness of the second type metal layer on the second plurality of nanostructure channel layers.

The terms “approximately” and “substantially” can indicate a value of a given quantity or magnitude that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first plurality of nanostructure channel layers that are arranged in a direction that is approximately perpendicular to a semiconductor substrate of a semiconductor device;
forming a second plurality of nanostructure channel layers that are arranged in the direction that is approximately perpendicular to the semiconductor substrate;
forming a first type metal layer wrapping around each of the first plurality of nanostructure channel layers;
forming a metal oxide layer on the first type metal layer; and
forming a second type metal layer on the metal oxide layer and on the second plurality of nanostructure channel layers,
wherein a first thickness of the second type metal layer on the metal oxide layer is different from a second thickness of the second type metal layer on the second plurality of nanostructure channel layers.

2. The method of claim 1, wherein forming the metal oxide layer comprises:
oxidizing a surface of the first type metal layer to form the metal oxide layer.

3. The method of claim 2, wherein oxidizing the surface of the first type metal layer comprises:
performing, using a solution that includes ozone (O₃) dissolved in deionized water, an oxide treatment operation on the surface of the first type metal layer.

4. The method of claim 2, wherein oxidizing the surface of the first type metal layer comprises:
performing a baking operation to oxidize the surface of the first type metal layer.

5. The method of claim 2, wherein oxidizing the surface of the first type metal layer comprises:
performing a plasma treatment operation on the surface of the first type metal layer to oxidize the surface of the first type metal layer.

6. The method of claim 2, wherein oxidizing the surface of the first type metal layer comprises:
performing, using an oxygen-containing gas, an oxide treatment operation on the surface of the first type metal layer.

7. The method of claim 1, wherein the first type metal layer comprises a titanium nitride (TiₓN_{y}); and
wherein the metal oxide layer comprises a titanium oxide (TiOₓ).

8. A semiconductor device, comprising:
a first plurality of nanostructure channel layers arranged in a direction that is approximately perpendicular to a semiconductor substrate of the semiconductor device;
a second plurality of nanostructure channel layers, adjacent to the first plurality of nanostructure channel layers, that are arranged in the direction that is approximately perpendicular to the semiconductor substrate;
a first gate structure, wrapping around the first plurality of nanostructure channel layers, comprising:
a p-type metal layer; and
a metal oxide layer comprising a material that includes an oxide of a p-type metal of the p-type metal layer; and
a second gate structure, wrapping around each of the second plurality of nanostructure channel layers, comprising an n-type metal layer,
wherein the n-type metal layer is included over the metal oxide layer of the first gate structure.

9. The semiconductor device of claim 8, wherein the p-type metal of the p-type metal layer comprises at least one of:
tungsten (W),
cobalt (Co),
tungsten nitride (WN), or
titanium nitride (TiN).

10. The semiconductor device of claim 8, wherein the p-type metal, of the p-type metal layer, has a work function that is greater than approximately 4.7 eV.

11. The semiconductor device of claim 8, wherein a thickness of a first portion of the n-type metal layer, that is on a sidewall of the first gate structure, is less than a thickness of a second portion of the n-type metal layer that is on a sidewall of the second gate structure.

12. The semiconductor device of claim 8, wherein a thickness of a first portion of the n-type metal layer, that is on a top surface of the first gate structure, is less than a thickness of a second portion of the n-type metal layer that is on a top surface of the second gate structure.

13. The semiconductor device of claim 8, wherein a ratio of a thickness of a portion of the n-type metal layer, that is on a top surface of the second gate structure, to a thickness of another portion of the n-type metal layer that is on a top surface of the first gate structure, is greater than approximately 1.2:1.

14. The semiconductor device of claim 8, wherein a ratio of a thickness of a portion of the n-type metal layer, that is on a side surface of the second gate structure, to a thickness of another portion of the n-type metal layer that is on a side surface of the first gate structure, is greater than approximately 1.2:1.

15. A method, comprising:
forming a first plurality of nanostructure channel layers that are arranged in a direction that is approximately perpendicular to a semiconductor substrate of a semiconductor device;
forming a second plurality of nanostructure channel layers that are arranged in the direction that is approximately perpendicular to the semiconductor substrate;
forming a p-type metal layer such that the p-type metal layer wraps around each of the first plurality of nanostructure channel layers and around each of the second plurality of nanostructure channel layers;
forming a masking layer over the first plurality of nanostructure channel layers;
removing, while the masking layer is over the first plurality of nanostructure channel layers, a portion of the p-type metal layer from the second plurality of nanostructure channel layers,
wherein a remaining portion of the p-type metal layer wrapping around the first plurality of nanostructure channel layers corresponds to a first gate structure;
removing the masking layer after removing the portion of the p-type metal layer;
performing, after removing the masking layer, an oxidation operation to form a metal oxide layer on the p-type metal layer of the first gate structure; and
forming, after forming the metal oxide layer, an n-type metal layer of a second gate structure such that the n-type metal layer wraps around each of the second plurality of nanostructure channel layers.

16. The method of claim 15, wherein performing the oxidation operation comprises:
performing a baking operation to oxidize a surface of the p-type metal layer.

17. The method of claim 16, wherein performing the baking operation comprises:
performing the baking operation at a temperature that is included in a range of approximately 230 degrees Celsius to approximately 300 degrees Celsius.

18. The method of claim 15, wherein a portion of the n-type metal layer is formed on the metal oxide layer; and
wherein a thickness of the portion of the n-type metal layer on the metal oxide layer is less than a thickness of the n-type metal layer that wraps around each of the second plurality of nanostructure channel layers.

19. The method of claim 15, wherein performing the oxidation operation comprises:
performing the oxidation operation using at least one of an ozone (O₃) gas or a nitrous oxide (N₂O) gas.

20. The method of claim 15, wherein performing the oxidation operation comprises:
performing the oxidation operation using an oxygen (O₂) plasma.
